(19) United States
(12) Patent Application Publication
(10) Pub. No.: US 2025/0142748 A1
(43) Pub. Date: May 1, 2025

(54) ACCESSORY FASTENING STRUCTURE AND STOPPER STRUCTURE PROVIDED IN HINGE PART OF FOLDABLE ELECTRONIC DEVICE

(71) Applicant: Samsung Electronics Co., Ltd., Suwon-si (KR)

(72) Inventor: Junwon LEE, Suwon-si (KR)

(21) Appl. No.: 18/956,696

(22) Filed: Nov. 22, 2024

Related U.S. Application Data
(63) Continuation of application No. PCT/KR2024/016299, filed on Oct. 24, 2024.

(30) Foreign Application Priority Data
Oct. 27, 2023 (KR) 10-2023-0145678
Dec. 13, 2023 (KR) 10-2023-0181036

(51) Int. Cl. H05K 5/02; F16C 11/04

(52) U.S. Cl. CPC H05K 5/0226; F16C 11/04

(57) ABSTRACT

An electronic device according to an embodiment of the disclosure may include: a first housing, a second housing disposed on one side of the first housing and rotatably connected to the first housing, a third housing disposed on one side of the second housing and rotatably connected to the second housing, a first hinge provided between the first housing and the second housing and having a first width, and a second hinge provided between the second housing and the third housing and having a second width greater than the first width. The second hinge may include a fastener receiving portion configured to receive a fastener of an accessory configured to be fastened thereto.

### CROSS-REFERENCE TO RELATED APPLICATIONS

This application is a continuation of International Application No. PCT/KR2024/016299 designating the United States, filed on Oct. 24, 2024, in the Korean Intellectual Property Receiving Office and claiming priority to Korean Patent Application Nos. 10-2023-0145678, filed on Oct. 27, 2023, and 10-2023-0181036, filed on Dec. 13, 2023, in the Korean Intellectual Property Office, the disclosures of each of which are incorporated by reference herein in their entireties.

### BACKGROUND

### Field

The disclosure relates to an electronic device including an accessory structure and a stopper structure provided in a hinge of a foldable electronic device.

### Description of Related Art

The use of foldable electronic devices that are folded and unfolded horizontally or vertically is increasing, and various functions are provided to foldable electronic devices. A foldable electronic device has first and second housings that are capable of rotating around a hinge module. A foldable electronic device has a plurality of housings that are capable of rotating via hinge modules and operating in an in-folding and/or out-folding manner.

Meanwhile, various types of cover accessories may be disposed on a foldable electronic device. The cover accessories may be used for a variety of purposes. For example, a cover accessory may protect a component of an electronic device, such as a hinge module, at least partially exposed outside the electronic device, from external shock. In addition, a strap may be coupled to the cover accessory to assist a user in easily holding the electronic device. Furthermore, an electronic pen (e.g., a stylus pen) configured to cooperate with an electronic device may be stored and used in a cover accessory.

The above information may be presented as related art for the purpose of assisting in understanding the disclosure. No assertion or decision is made as to whether any of the above might be applicable as prior art with regard to the disclosure.

A foldable electronic device may include a multi-foldable electronic device in which a first housing, a second housing, and a third housing perform a folding or unfolding operation around a hinge (e.g., a hinge module, a hinge device, and a hinge assembly). The multi-foldable electronic device may have a first housing, a second housing, and a third housing sequentially connected via hinges. In the multi-foldable electronic device, in the state in which two housings are folded to face each other, the remaining housing may rotate to cover the exterior of one of the two housings. For example, in the state in which a first housing and a second housing are folded such that the front surface of the first housing faces the front surface of the second housing, the third housing may rotate through via a hinge to cover the rear surface of the first housing. In summary, when the electronic device is in a folded state, the first housing and the second housing face each other, and the second housing may be located between the first housing and the third housing. In this case, since it is necessary for the third housing to rotate further relative to the second housing by the thickness of the first housing, the rotation radius between the second housing and the third housing may be greater than the rotation radius between the first housing and the second housing. Accordingly, a first hinge interconnecting the first housing and the second housing may be a relatively slim hinge, and the second hinge interconnecting the second housing and the third housing may be a relatively wide hinge.

Meanwhile, when the rotation angle between the first housing and the second housing and/or the second housing and the third housing exceeds 180 degrees when the electronic device is in the unfolded state, the electronic device may be damaged. Accordingly, the plurality of housings may be designed such that the ends interconnected by the hinge modules come into contact with each other when the electronic device is in the unfolded state. For example, when the electronic device is unfolded, the first housing and the second housing can be prevented from being excessively unfolded as end portions connected to the first hinge are brought into contact with each other. However, due to the folding characteristics of the multi-foldable electronic device described above, the width of the second hinge may be greater than the width of the first hinge. Accordingly, when the electronic device is in the unfolded state, a space or step may be formed between the second housing and the third housing. In this case, due to the space or step formed between the second and third housings, the second housing and the third housing may be folded beyond 180 degrees, which may cause damage to the electronic device. In addition, when external force is applied to the space or step formed between the housings, damage may occur in the electronic device.

### SUMMARY

An electronic device according to an example embodiment of the disclosure may include: a first housing, a second housing disposed on one side of the first housing and rotatably connected to the first housing, a third housing disposed on one side of the second housing and rotatably connected to the second housing, a first hinge provided between the first housing and the second housing and having a first width, and a second hinge provided between the second housing and the third housing and having a second width greater than the first width. The second hinge may include a fastener receiving portion configured to receive a fastener of an accessory.

According to an example embodiment of the disclosure, an electronic device may include a plurality of housings rotatably connected with a hinge interposed therebetween, and a stopper located in a space provided between the plurality of housings on the hinge as the electronic device is unfolded.

According to an example embodiment of the disclosure, when the electronic device is in the unfolded state, an accessory and/or a stopper can be located in the space or step formed between housings. When the electronic device is in the unfolded state, the accessory and the stopper may prevent and/or block the housings from being excessively unfolded by being located in the space or step formed between the housings.

### BRIEF DESCRIPTION OF THE DRAWINGS

With regard to the description of the drawings, the same or like reference signs may be used to designate the same or like elements. Further, the above and other aspects, features and advantages of certain embodiments of the present disclosure will be more apparent from the following detailed description, taken in conjunction with the accompanying drawings, in which:

FIG. 1A is a diagram illustrating a front view of an example electronic device in an unfolded state according to various embodiments;

FIG. 1B is a diagram illustrating a rear view of an example electronic device in a folded state according to various embodiments;

FIG. 2 is a diagram illustrating the electronic device in the state in which the first housing is folded relative to the second housing according to various embodiments;

FIG. 3 is a diagram illustrating the electronic device in the state in which the first and third housings are folded relative to the second housing according to various embodiments;

FIG. 4A is a perspective view illustrating a state in which an accessory is coupled to a second hinge of an electronic device, according to various embodiments;

FIG. 4B is a diagram illustrating a front view of various types of accessories to be coupled to the electronic device illustrated in FIG. 4A, according to various embodiments;

FIG. 4C is a diagram illustrating a rear view of one of various types of accessories to be coupled to the electronic device illustrated in FIG. 4A, according to various embodiments;

FIG. 5A is a diagram illustrating a state in which a first coupling hole and a second coupling hole, to which an accessory is coupled, are provided in one end portion and the other end portion of the second hinge, according to various embodiments;

FIGS. 5B, 5C and 5D include a perspective view and diagrams illustrating an example process in which a first fastener and a second fastener of an accessory are fastened to the first coupling hole and the second coupling hole in the second hinge, according to various embodiments;

FIG. 6A is a diagram illustrating a front view of various types of accessories to be fastened to the second hinge in a clipping manner, according to various embodiments;

FIG. 6B is a diagram illustrating cut portions in a fastener of one of the accessories illustrated in FIG. 6A according to various embodiments;

FIG. 7 is a diagram illustrating the state in which the accessory of FIG. 6A is fastened to the second hinge according to various embodiments;

FIG. 8A is a perspective view illustrating the state in which a groove into which a lug of an accessory is inserted is provided in the second hinge, according to various embodiments;

FIGS. 8B and 8C are perspective views illustrating an example process in which an accessory is fastened to the second hinge of the electronic device via a hook, according to various embodiments;

FIG. 9 is a diagram illustrating a state in which a lug of an accessory is inserted into the groove of the second hinge according to various embodiments;

FIG. 10 is a perspective view of the second hinge to which an accessory including a hook is coupled according to various embodiments;

FIG. 11A is a perspective view illustrating an example process in which an accessory including a hook configured to cooperate with an elastic member is coupled to the second hinge of the electronic device, according to various embodiments

FIG. 11B is a diagram illustrating an accessory including a hook configured to cooperate with an elastic member, according to various embodiments;

FIG. 12A is a perspective view of a second hinge including a stopper, according to various embodiments;

FIG. 12B is a diagram illustrating a state in which the stopper is located in a space formed between the second housing and the third housing when the electronic device is in the unfolded state, according to various embodiments;

FIG. 13A is a diagram illustrating a plan view of a stopper located in an opening provided in a hinge housing, according to various embodiments;

FIG. 13B is a perspective cross-sectional view of a second hinge taken along line 13a-13a indicated in FIG. 13A according to various embodiments;

FIGS. 14A and 14B include a perspective view and a diagram illustrating an example process in which a stopper moves relative to a hinge housing in cooperation with a rotation part of a hinge device, according to various embodiments;

FIGS. 15A and 15B include a perspective view and a diagram illustrating an example process in which a stopper moves relative to a hinge housing in cooperation with a hinge device via gears, according to various embodiments;

FIGS. 16A and 16B are perspective views illustrating an example process in which a stopper moves relative to a hinge housing in cooperation with a hinge device via magnets, according to various embodiments;

FIGS. 17A, 17B and 17C include a diagram and perspective views illustrating an example process in which a stopper moves with respect to a hinge housing in cooperation with cams of a hinge device, according to various embodiments;

FIG. 18A is a perspective view illustrating a state in which a stopper configured to cooperate with a hinge device is located in one end portion of the second hinge, according to various embodiments; and

FIGS. 18B and 18C are perspective views illustrating an example process in which a stopper moves with respect to a hinge housing in conjunction with a hinge device, according to various embodiments.

### DETAILED DESCRIPTION

In the following description, various example embodiments of the disclosure will be described in greater detail with reference to the accompanying drawings. It should be appreciated that the various example embodiments and the terms used therein are not intended to limit the technological features set forth herein to particular embodiments and the disclosure includes various changes, equivalents, or alternatives for a corresponding embodiment.

With regard to the description of the drawings, similar reference numerals may be used to designate similar or relevant elements. A singular form of a noun corresponding to an item may include one or more of the items, unless the relevant context clearly indicates otherwise.

As used herein, each of such phrases as “A or B,” “at least one of A and B,” “at least one of A or B,” “A, B, or C,” “at least one of A, B, and C,” and “at least one of A, B, or C” may include all possible combinations of the items enumerated together in a corresponding one of the phrases. Such terms as “a first,” “a second,” “the first,” and “the second” may be used to simply distinguish a corresponding element from another, and does not limit the elements in other aspect (e.g., importance or order). If an element (e.g., a first element) is referred to, with or without the term “operatively” or “communicatively”, as “coupled with/to” or “connected with/to” another element (e.g., a second element), the element may be coupled/connected with/to the other element directly (e.g., wiredly), wirelessly, or via a third element.

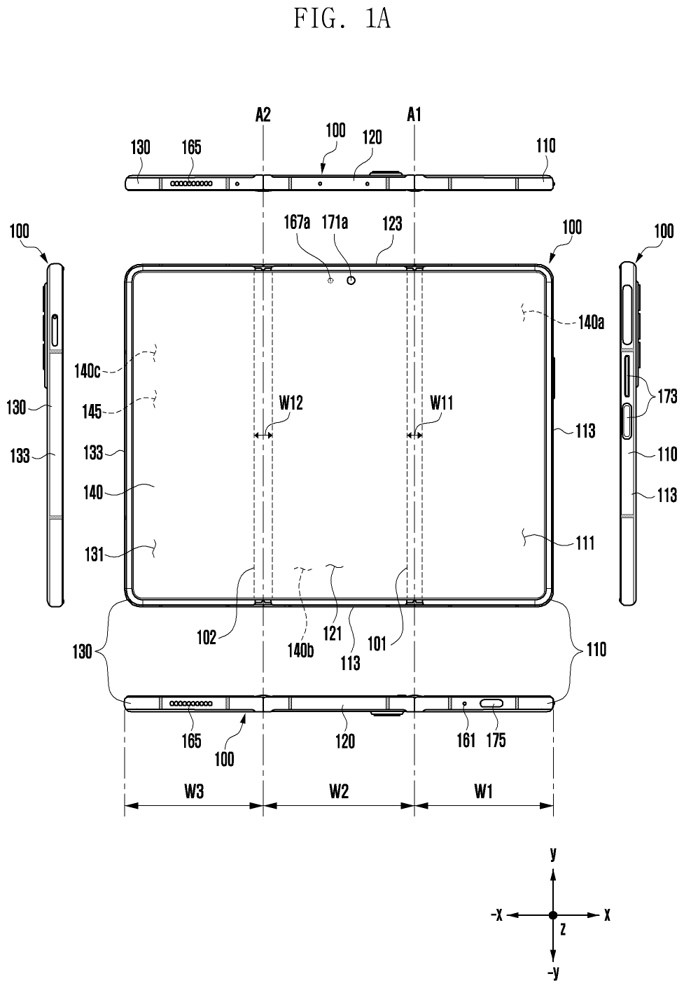

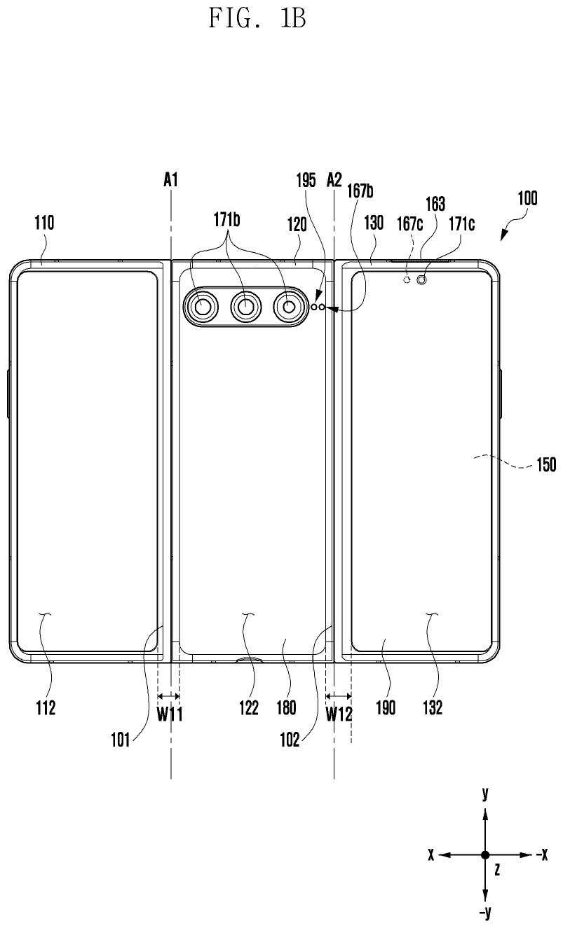

FIG. 1A is a diagram illustrating a front view of an electronic device in an unfolded state according to various embodiments. FIG. 1B is a diagram illustrating a rear view of an electronic device in a folded state according to various embodiments.

Referring to FIGS. 1A and 1B, an electronic device 100 according to various embodiments of the disclosure may include a first housing 110, a second housing 120, a third housing 130, a first hinge 101, a second hinge 102, and/or a flexible display 140.

According to an embodiment, the first housing 110 may be foldably coupled to a first side of the second housing 120 (e.g., in the x-axis direction). In an embodiment, the first hinge 101 may be located between the first housing 110 and the second housing 120. In an embodiment, the first housing 110 and the second housing 120 may be rotatably coupled to each other via the first hinge 101. In an embodiment, the first hinge 101 may include a hinge module, a hinge device, a hinge plate, or a hinge assembly located between the first housing 110 and the second housing 120. In an embodiment, the hinge module, the hinge device, the hinge plate, or the hinge assembly may be coupled to the first housing 110 and the second housing 120. In addition, the first hinge 101 may include all components of a hinge that rotatably interconnects the first housing 110 and the second housing 120.

In an embodiment, the first hinge 101 may be coupled between the first housing 110 and the second housing 120. The first hinge 101 may be disposed to allow the first housing 110 and the second housing 120 to be folded or unfolded with respect to each other. The first housing 110 and the second housing 120 may be coupled to be rotatable about a first folding axis A1 using the first hinge 101.

According to an embodiment, the second housing 120 may be foldably coupled to one side of the first housing 110 (e.g., in the −x-axis direction). The second housing 120 has a first side (e.g., in the x-axis direction) operatively coupled to at least a portion of the first housing 110, and a second side (e.g., in the −x-axis direction) operatively coupled to at least a portion of the third housing 130.

According to an embodiment, the third housing 130 may be foldably coupled to the second side of the second housing 120 (e.g., in the −x-axis direction). In an embodiment, the second hinge 102 may be located between the second housing 120 and the third housing 130. In an embodiment, the second housing 120 and the third housing 130 may be rotatably coupled to each other via the second hinge 102. In an embodiment, the second hinge 102 may include a hinge module, a hinge device, a hinge plate, or a hinge assembly located between the second housing 120 and the third housing 130. In an embodiment, the hinge module, the hinge device, the hinge plate, or the hinge assembly may be coupled to the second housing 120 and the third housing 130. In addition, the second hinge 102 may include all components of a hinge that rotatably interconnects the second housing 120 and the third housing 130.

In an embodiment, the second hinge 102 may be coupled between the second housing 120 and the third housing 130. The second hinge 102 may be disposed to allow the second housing 120 and the third housing 130 to be folded or unfolded with respect to each other. The second hinge 102 may include a hinge device, a hinge module, a hinge plate, or a hinge assembly. The second housing 120 and the third housing 130 may be coupled to be rotatable about a second folding axis A2 using the second hinge 102. According to an embodiment, the one side of the third housing 130 (e.g., in the x-axis direction) may be foldably coupled to the second side of the second housing 120 (e.g., in the −x-axis direction).

According to an embodiment, the electronic device 100 may be configured such that, when the electronic device 100 is folded in a normal order, the first housing 110 is folded first relative to the second housing 120 via the first hinge 101, and the third housing 130 is folded later relative to the second housing 120 via the second hinge 102. According to an embodiment, when the third housing 130 is folded first relative to the second housing 120 via the second hinge 102 and the first housing 110 is folded later relative to the second housing 120 via the first hinge 101, the electronic device 100 may be configured to recognize this case as a normal folding order.

According to an embodiment, the width w1 of the first housing 110 in the horizontal direction (e.g., the x-axis direction and the −x-axis direction) may be configured to be smaller than the width w2 of the second housing 120 in the horizontal direction (e.g., the x-axis direction and the −x-axis direction). The width w2 of the second housing 120 in the horizontal direction (e.g., the x-axis direction and the −x-axis directions) may be configured to be substantially the same as the width w3 of the third housing 130 in the horizontal direction (e.g., the x-axis and the −x-axis direction). According to an embodiment, the width w3 of the third housing 130 in the horizontal direction (e.g., the x-axis direction and the −x-axis direction) may be configured to be greater than the width w2 of the second housing 120 in the horizontal direction (e.g., the x-axis direction and the −x-axis direction).

According to an embodiment, the first housing 110 and the second housing 120 may be disposed on opposite sides of the first folding axis A1 on which the first hinge 101 is disposed, and may have an asymmetrical shape with respect to the first folding axis A1. According to an embodiment, the first housing 110 and the second housing 120 may have a symmetrical shape with respect to the first folding axis A1. The angle or distance between the first housing 110 and the second housing 120 may vary depending on whether the foldable electronic device 100 is in the unfolded state, the folded state, or the intermediate state.

According to an embodiment, the second housing 120 and the third housing 130 may be disposed on opposite sides of the second folding axis A2 on which the second hinge 102 is disposed, and may have a substantially symmetrical shape with respect to the second folding axis A2. According to an embodiment, the second housing 120 and the third housing 130 may have an asymmetrical shape with respect to the second folding axis A2. The angle or distance between the second housing 120 and the third housing 130 may vary depending on whether the foldable electronic device 100 is in the unfolded state, the folded state, or the intermediate state.

According to an embodiment, the width w12 of the second hinge 102 may be greater than the width w11 of the first hinge 101. For example, when the first housing 110 is folded relative to the second housing 120, and the third housing 130 is folded relative to the second housing 120, so that the third housing 130 is disposed above the first housing 110, the width w12 of the second hinge 102 may be greater than the width w11 of the first hinge 101. For example, the first hinge 101 may include a slim hinge with a narrow width. For example, the second hinge 102 may include a wide hinge that is wider than the first hinge 101.

According to an embodiment, since the width w12 of the second hinge 102 is configured to be greater than the width w11 of the first hinge 101, a portion of the second housing 120 may be brought into contact with a portion of the first housing 110 when the third housing 130 is folded first toward the second housing 102. In this state, when the first housing 110 is folded later toward the second housing 120, the first housing 110 may collide with a portion of the third housing 130 and be damaged.

According to an embodiment, the flexible display 140 may be disposed across at least a portion of the front surfaces of the first housing 110, the second housing 120, and the third housing 130 (e.g., in the z-axis direction). The flexible display 140 may be a first display, a foldable display, or a main display. According to an embodiment, a sub-display 150 (e.g., a second display) may be disposed on the rear surface of the third housing 130 (e.g., in the −z-axis direction).

The surface on which the flexible display 140 is disposed may be referred, for example, to as the front surface of the electronic device 100 (e.g., in the z-axis direction), and the surface opposite to the front surface may be defined as the rear surface of the electronic device 100 (e.g., in the −z-axis direction). The surface surrounding the space between the front surface and the rear surface may be defined as the side surface of the electronic device 100.

According to an embodiment, the flexible display 140 may include a first display area 140a disposed on the first housing 110, a second display area 140b disposed on the second housing 120, and a third display area 140c disposed on the third housing 130. The first display area 140a, the second display area 140b, and the third display area 140c may be integrated to form the flexible display 140. According to an embodiment, when the electronic device 100 is unfolded, the flexible display 140 may be configured to be disposed on most of the front surface of the electronic device 100 (e.g., in the z-axis direction). At least a portion of the flexible display 140 may be transformed into a flat or curved surface. The division of the flexible display 140 into the first display area 140a, the second display area 140b, and the third display area 140c may be an example physical division. The flexible display 140 may be fabricated as an overall seamless single screen.

According to an embodiment, when the electronic device 100 is unfolded, the first housing 110 may include a first surface 111 connected to at least a portion of the first hinge 101 and disposed to face the front of the electronic device 100, a second surface 112 oriented in the opposite direction to the first surface 111, and/or a first side surface member 113 surrounding at least a portion of the first space between the first surface 111 and the second surface 112.

According to an embodiment, when the electronic device 100 is unfolded, the second housing 120 may include a third surface 121 connected to at least a portion of the first hinge 101 and at least a portion of the second hinge 102 and disposed to face the front of the electronic device 100, a fourth surface 122 oriented in the opposite direction to the third surface 121, and/or a second side surface member 123 surrounding at least a portion of the second space between the third surface 121 and the fourth surface 122.

According to an embodiment, when the electronic device 100 is unfolded, the third housing 130 may include a fifth surface 131 connected to at least a portion of the second hinge 102 and disposed to face the front of the electronic device 100, a sixth surface 132 oriented in the opposite direction to the fifth surface 131, and/or a third side surface member 133 surrounding at least a portion of the third space between the fifth surface 131 and the sixth surface 132.

According to an embodiment, when the electronic device 100 is unfolded, the first surface 111, the third surface 121, and the fifth surface 131 may be oriented in substantially the same direction (e.g., the z-axis direction). When the electronic device 100 is unfolded, the second surface 112, the fourth surface 122, and the sixth surface 132 may be oriented in substantially the same direction (e.g., the −z-axis direction).

According to an embodiment, when the first housing 110 and the second housing 120 of the electronic device 100 are folded, the first surface 111 and the third surface 121 may be disposed to face each other. When the second housing 120 and the third housing 130 of the electronic device 100 are folded, the third surface 121 and the fifth surface 131 may be disposed to face each other.

According to an embodiment, the electronic device 100 may include a recess 145 provided to accommodate the flexible display 140 through structural coupling of the first housing 110, the second housing 120, and the third housing 130. The recess 145 may have substantially the same size as the flexible display 140.

According to an embodiment, when the electronic device 100 is unfolded, the first housing 110, the second housing 120, and the third housing 130 may form an angle of about 180 degrees, and the first display area 140a, the second display area 140b, and the third display area 140c of the flexible display 140 may be disposed to be oriented in substantially the same direction (e.g., the z-axis direction) while forming substantially the same plane.

According to an embodiment, the first housing 110 and the second housing 120 may form an angle where the first and second housings can be stopped at a predetermined folding angle between the folded state and the unfolded state using the first hinge 101 (e.g., a free-stop function). In various embodiments, the first housing 110 may be rotated to the rear surface of the second housing 120 using the first hinge 101 while being pressed in the unfolding direction (e.g., the −z-axis direction) with reference to a predetermined inflection angle.

According to an embodiment, the second housing 120 and the third housing 130 may form an angle where the second and third housings can be stopped at a predetermined folding angle between the folded state and the unfolded state using the second hinge 102. In various embodiments, the third housing 130 may be rotated to the rear surface of the second housing 120 using the second hinge 102 while being pressed in the unfolding direction (e.g., the −z-axis direction) with reference to a predetermined inflection angle.

According to an embodiment, the flexible display 140 may be disposed to be supported by the first surface 111 of the first housing 110, the first hinge 101, the third surface 121 of the second housing 120, the second hinge 102, and the fifth surface 131 of the third housing 130. In an embodiment, the sub-display 150 may be disposed in the inner space of the third housing 130 to be at least partially visible from the outside through the sixth surface 132. In various embodiments, the sub-display 150 may be disposed in the inner space of the first housing 110 to be visible from the outside through the second surface 112.

According to an embodiment, the flexible display 140 may be mainly used when the electronic device 100 is in the unfolded state, and the sub-display 150 may be mainly used when the foldable electronic device 100 is in the folded state. The flexible display 140 may be disposed in an accommodation space defined by the first housing 110, the second housing 120, and the third housing 130. For example, the flexible display 140 may be disposed in the recess 145 defined by the first housing 110, the second housing 120, and the third housing 130.

According to an embodiment, the electronic device 100 may include a first rear surface cover 180 disposed on the fourth surface 122 of the second housing 120 and a second rear surface cover 190 disposed on the sixth surface 132 of the third housing 130. In various embodiments, at least a portion of the first rear surface cover 180 may be integrated with a portion of the second side surface member 123. In various embodiments, at least a portion of the second rear surface cover 190 may be integrated with a portion of the third side surface member 233. According to an embodiment, at least one of the first rear surface cover 180 and the second rear surface cover 190 may be made of a substantially transparent plate (e.g., a glass plate including various coating layers, or a polymer plate) or an opaque plate.

According to an embodiment, the first rear surface cover 180 may be made of, for example, coated or colored glass, ceramic, polymer, metal (e.g., aluminum, stainless steel (STS), or magnesium), or an opaque plate such as a combination of two or more of these materials. The second rear surface cover 190 may be made of a substantially transparent plate of, for example, glass or polymer. In this case, the sub-display 150 may be disposed in the inner space of the third housing 130 to be visible from the outside through the second rear surface cover 190.

According to an embodiment, the electronic device 100 may include at least one of an input module 161, sound output modules 163 and 165, sensor modules 167a, 167b, and 167c, camera modules 171a, 171b, and 171c, key input devices 173, an indicator (not illustrated), or a connector port 175. In various embodiments, at least one of the above-mentioned components may be omitted from the electronic device 100, or at least one other component may be additionally included in the electronic device 100.

According to an embodiment, the input module 161 may include at least one microphone disposed to detect the direction of sound.

According to an embodiment, the sound output modules 163 and 165 may include at least one speaker. The sound output modules 163 and 165 may include a call receiver 163 disposed through the sixth surface 132 of the third housing 130 and/or a speaker 165 disposed in at least a portion of the upper portion (e.g., in the y-axis direction) and the lower portion (e.g., in the −y-axis direction) of the third side surface member 133 of the third housing 130.

According to an embodiment, the input module 161, the sound output modules 163 and 165, and the connector port 175 may be disposed in the spaces of the first housing 110, the second housing 120, and/or the third housing 130, and may be exposed to the external environment through one or more holes provided in the first housing 110, the second housing 120, and/or the third housing 130. In an embodiment, the holes provided in the first housing 110, the second housing 120, and/or the third housing 130 may be commonly used for the input module 161 and the sound output modules 163 and 165. In an embodiment, the sound output modules 163 and 165 may include a speaker that operates without holes provided in the first housing 110 and/or the third housing 130 (e.g., a piezo speaker).

According to an embodiment, the camera modules 171a, 171b, and 171c may include a first camera module 171a disposed on the third surface 121 of the second housing 120, a second camera module 171b disposed on the fourth surface 122 of the second housing 120, and/or a third camera module 171c disposed on the sixth surface 132 of the third housing 130. In an embodiment, the electronic device 100 may include a flash 195 located near the second camera module 171b. The flash 195 may include, for example, a light-emitting diode or a xenon lamp. According to an embodiment, the camera modules 171a, 171b, and 171c may include one or more lenses, an image sensor, and/or an image signal processor. In an embodiment, at least one of the camera modules 171a, 171b, and 171c may include two or more lenses (e.g., wide-angle and telephoto lenses) and image sensors, and the camera modules may be disposed together on one surface of the first housing 110, the second housing 120, and/or the third housing 130.

According to an embodiment, the sensor modules 167a, 167b, and 167c may generate electrical signals or data values corresponding to an internal operating state or an external environmental state of the electronic device 100. According to an embodiment, the censor modules 167a, 167b, and 167c may include a first sensor module 167a disposed on the third surface 121 of the second housing 120, a second sensor module 167b disposed on the fourth surface 122 of the second housing 120, and/or a third sensor module 167c disposed on the sixth surface 132 of the third housing 130. In various embodiments, the sensor modules 167a, 167b, and 167c may include at least one of a gesture sensor, a grip sensor, a color sensor, an infrared (IR) sensor, an illumination sensor, an ultrasonic sensor, an iris recognition sensor, or a distance detection sensor (e.g., a time-of-flight (TOF) sensor or a light detection and ranging (LiDAR) sensor).

According to an embodiment, the electronic device 100 may further include at least one of sensor modules (not illustrated) such as a Hall sensor, an acceleration sensor, an angular velocity sensor, a gyro sensor, a folding detection sensor, a proximity sensor, an air pressure sensor, a magnetic sensor, a biometric sensor, a temperature sensor, a humidity sensor, or a fingerprint recognition sensor.

According to an embodiment, the key input devices 173 may be disposed to be exposed outside through the first side surface member 113 of the first housing 110. In an embodiment, the key input device 173 may be disposed to be exposed outside through the third side surface member 133 of the third housing 130. In an embodiment, the electronic device 100 may not include some or all of the key input devices 173, and a key input device 173, which is not included, may be implemented in another form, such as a soft key, on at least one display 140 or 150. In various embodiments, the key input devices 173 may be implemented using pressure sensors included in the at least one display 140 or 150. In an embodiment, the key input devices 173 may include a power button and/or a volume control button of the electronic device 100.

According to an embodiment, the connector ports 175 may include a connector (e.g., a USB connector or an interface connector port module (IF module)) configured to transmit/receive power and/or data to/from an external electronic device. In an embodiment, the connector ports 175 may perform a function for transmitting/receiving an audio signal to and from the external electronic device, or may further include a separate connector port (e.g., an ear jack hole) for an audio signal transmitting/receiving function.

According to an embodiment, one or more camera modules 171a and 171c among the camera modules 171a, 171b, and 171c, one or more sensor modules 167a and 167c among the sensor modules 167a, 167b, and 167c, and/or an indicator may be disposed to be exposed through one or more displays 140 and 150. For example, the one or more camera modules 171a and 171c, the one or more sensor modules 167a and 167c, and/or the indicator may be disposed in the inner spaces of the one or more housings 110, 120, and 130 below the active areas (display areas) of the one or more displays 140 and 150, and may be disposed to come into contact with the external environment through openings perforated up to the cover member (e.g., a window layer (not illustrated) of the flexible display 140 and/or the second rear surface cover 190) or a transparent area.

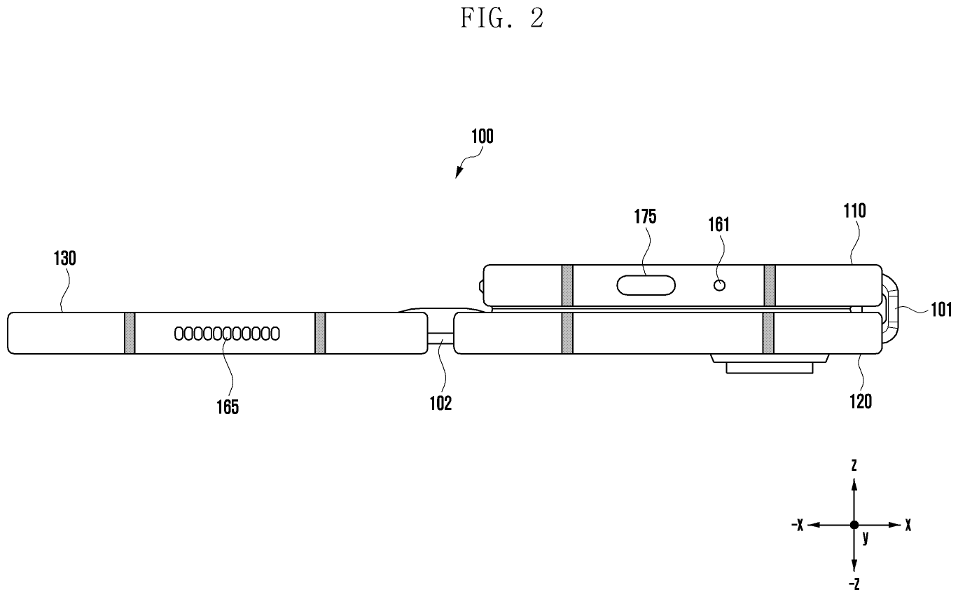

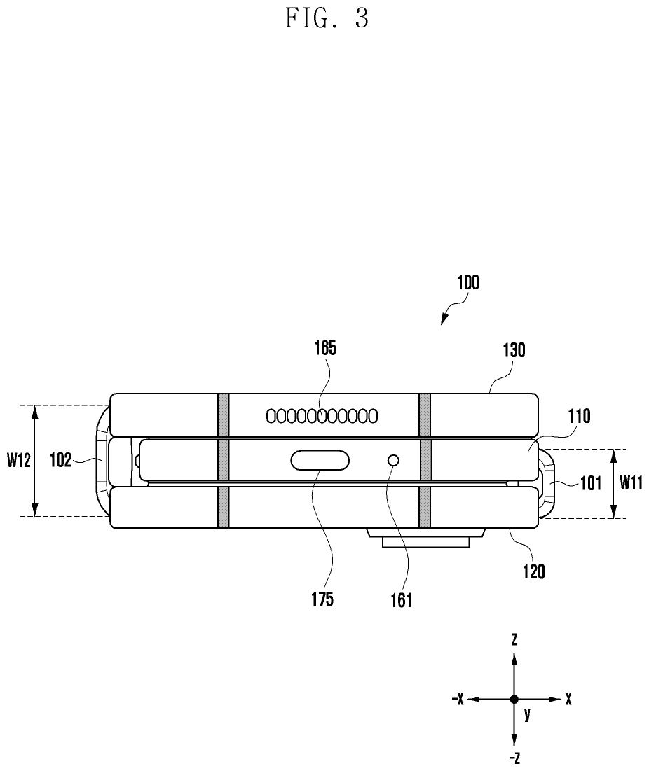

FIG. 2 is a diagram illustrating the electronic device 100 in the state in which the first housing 110 is folded relative to the second housing 120 according to various embodiments. FIG. 3 is a diagram illustrating the electronic device in the state in which the first and third housings are folded relative to the second housing according to various embodiments.

According to an embodiment, FIG. 2 may be a view of the electronic device 100 in the state in which the first housing is folded toward the second housing 120, viewed in the −y-axis direction. According to an embodiment, FIG. 3 may be a view of the electronic device 100 in the state in which the first housing 110 is folded first toward the second housing 120 and the third housing 130 is folded toward the second housing 120 later (e.g., a normal folding order), viewed in the −y-axis direction.

Referring to FIGS. 2 and 3, the electronic device 100 may include a first housing 110, a second housing 120, a third housing 130, a first hinge 101, and a second hinge 102.

According to an embodiment, the first housing 110 may be folded first to the upper portion of the second housing 120 (e.g., the z-axis direction) via the first hinge 101 (e.g., a slim hinge).

According to an embodiment, after the first housing 110 is folded relative to the second housing 120 via the first hinge 101, the third housing 130 may be folded toward the second housing 120 via the second hinge 102 (e.g., a wide hinge) to be disposed on the upper portion of the first housing 110 (e.g., the z-axis direction).

According to an embodiment, when the first housing 110 is folded first toward the second housing 120 via the first hinge 101, and the third housing 130 is folded later toward the second housing 120 via the second hinge 102, the electronic device 100 may recognize this as a normal folding order. According to an embodiment, when the third housing 130 is folded first toward the second housing 120 via the second hinge 102, and the first housing 110 is folded later toward the second housing 120 via the first hinge 101, the electronic device 100 may recognize this as an abnormal folding order.

According to an embodiment, the first hinge 101 may have a first width w11. The second hinge 102 may have a second width w12. The second width w12 may be wider than the first width w11. According to an embodiment, since the first housing 110 should be folded relative to the second housing 120, and the third housing 130 should be folded relative to the second housing 120 to be disposed above the first housing 110 (e.g., the z-axis direction), the second width w12 of the second hinge 102 may be configured to be greater than the first width w11 of the first hinge 101. For example, the first hinge 101 may include a slim hinge with a narrow width. For example, the second hinge 102 may include a wide hinge that is wider than the first hinge 101.

According to an embodiment, since the second width w12 of the second hinge 102 is configured to be greater than the first width w11 of the first hinge 101, a portion of the second housing 220 may be brought into contact with a portion of the first housing 110 when the third housing 130 is folded first toward the second housing 220. In this state, when the first housing 110 is folded later toward the second housing 120, the first housing 110 may collide with a portion of the third housing 130 and be damaged.

According to an embodiment, the risk of damage to the electronic device 100 may be reduced only when the first housing 110 is folded first toward the second housing 120, and the third housing 130 is folded later toward the second housing 120 (e.g., normal folding order).

According to an embodiment, when the third housing 130 is folded first toward the second housing 120 and the first housing 110 is folded later toward the second housing 120 (e.g., abnormal folding order), the electronic device 100 may provide at least one notification (e.g., warning sound, vibration, and/or pop-up message) to a user.

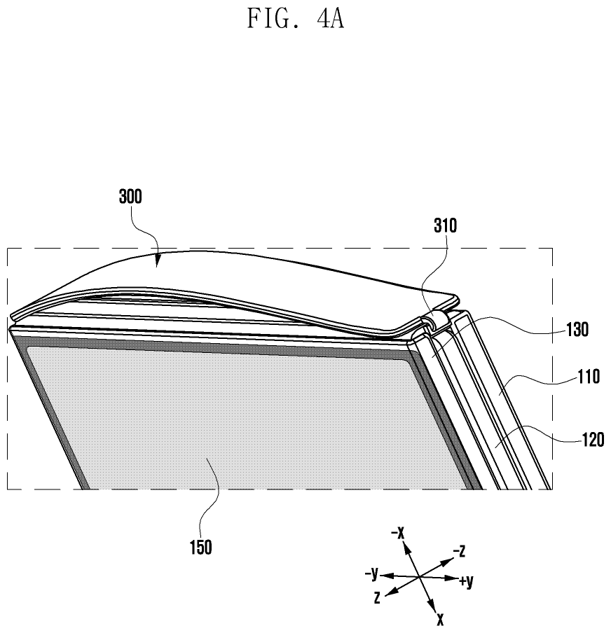

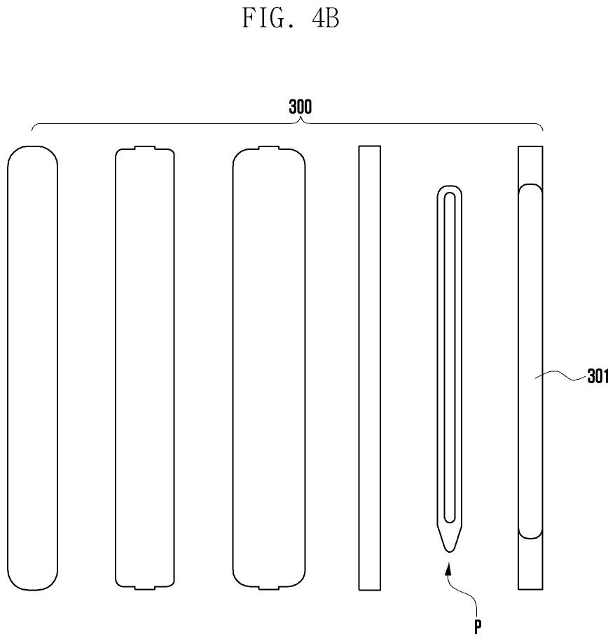

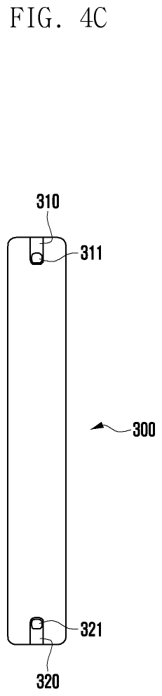

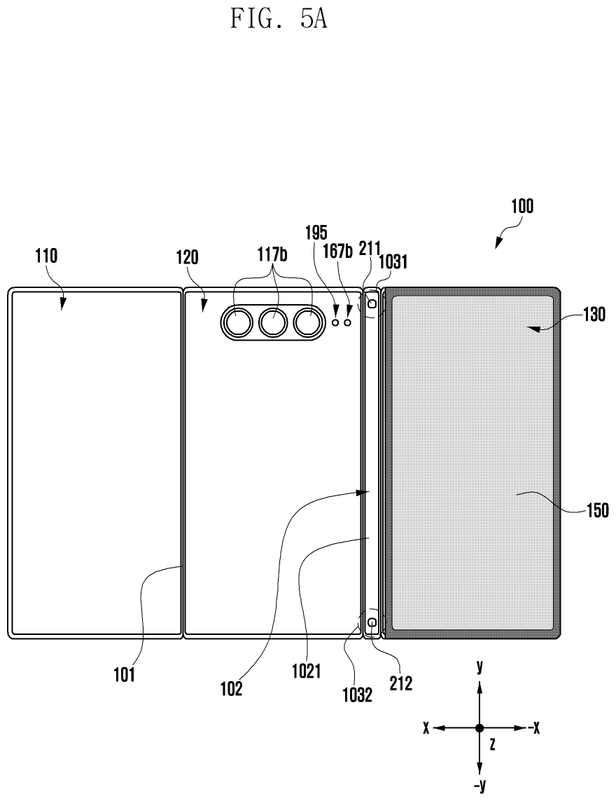

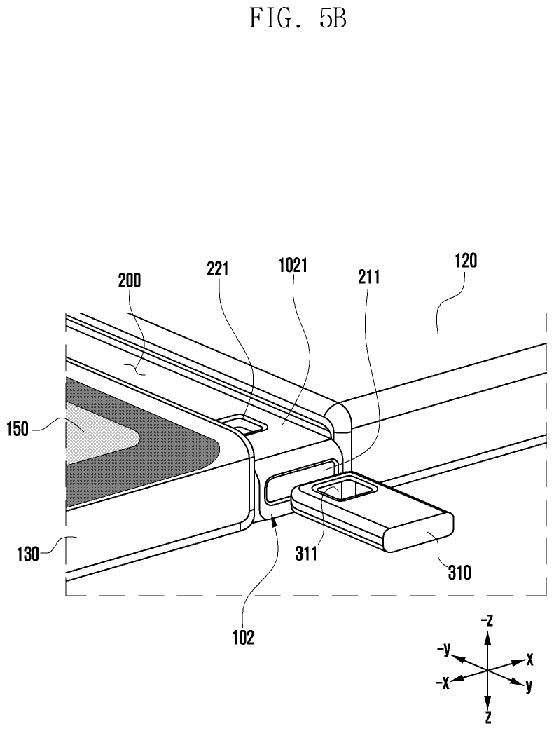

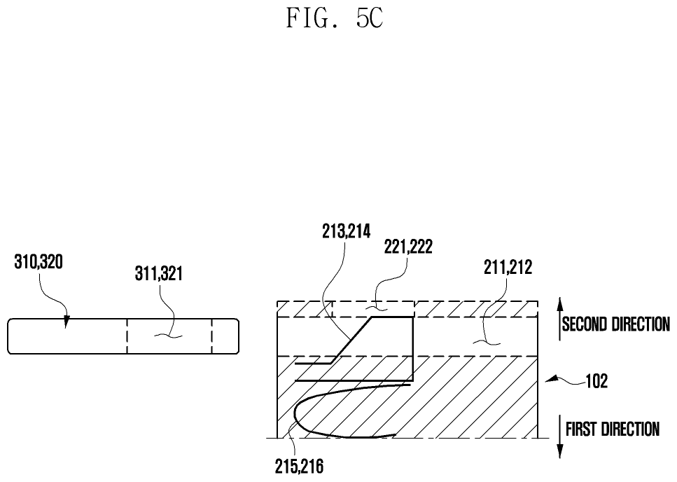

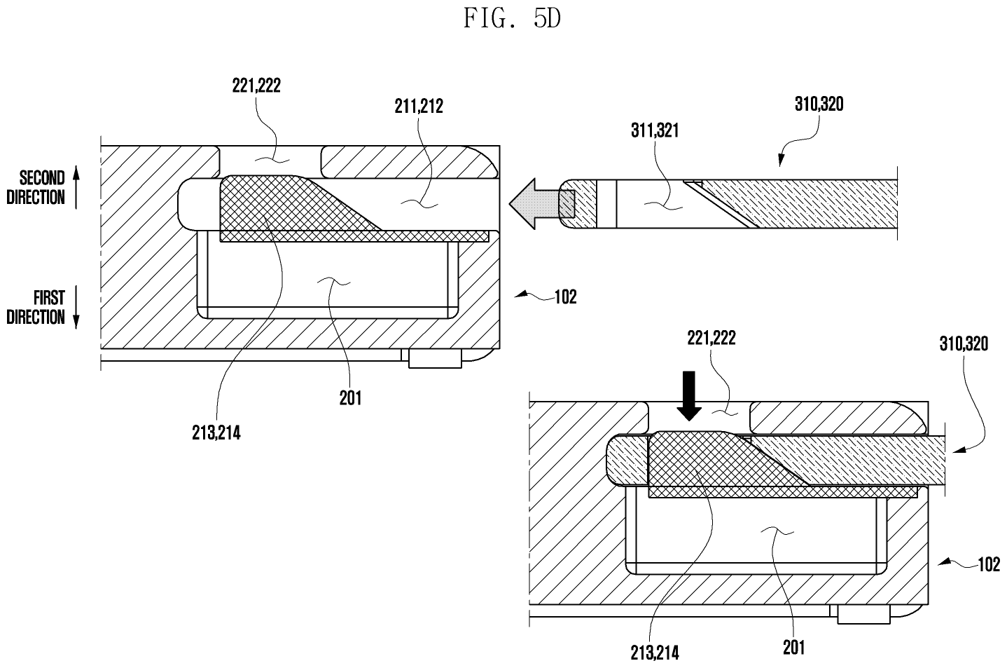

FIG. 4A is a perspective view illustrating a state in which an accessory is coupled to a second hinge of an electronic device, according to various embodiments. FIG. 4B is a diagram illustrating example front views of various types of accessories to be coupled as illustrated in FIG. 4A, according to various embodiments. FIG. 4C is a rear view of one of various types of accessories to be coupled as illustrated in FIG. 4A, according to various embodiments. FIG. 5A is a diagram illustrating a state in which a first coupling hole and a second coupling hole, to which an accessory is fastened, are provided in one end portion and the other end portion of the second hinge, according to various embodiments. FIGS. 5B, 5C and 5D include a perspective view and diagrams illustrating an example process in which a first fastener and a second fastener of an accessory are fastened to the first coupling hole and the second coupling hole in the second hinge, according to various embodiments.

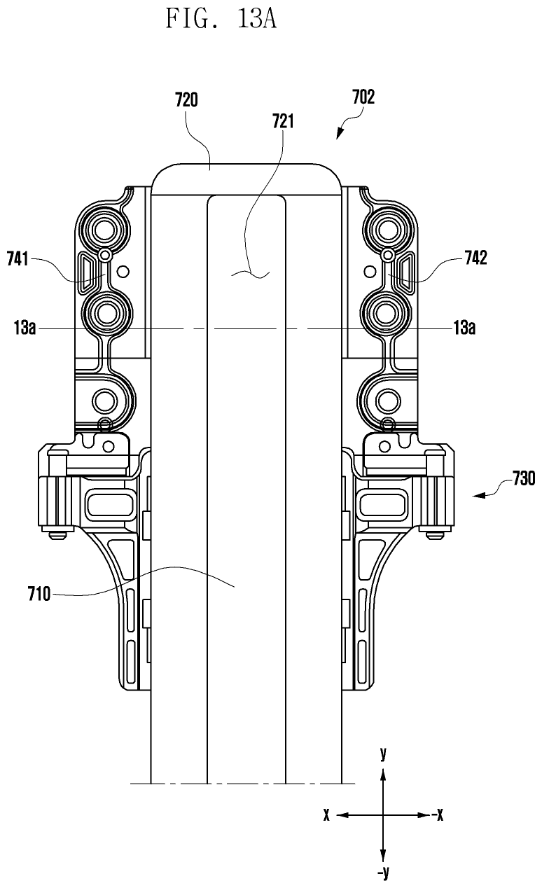

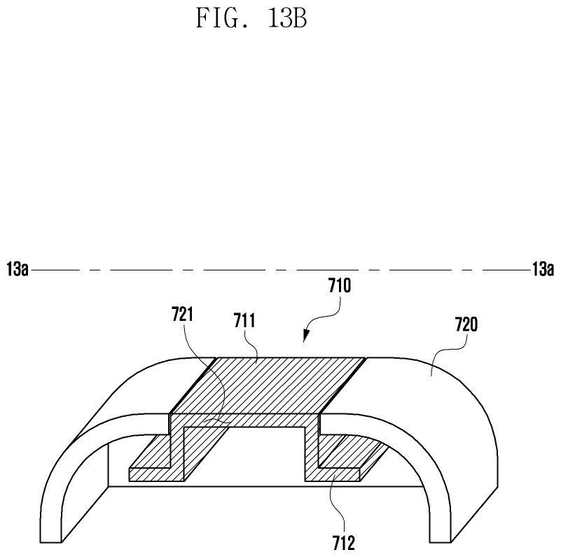

According to an embodiment, the first housing 110, the second housing 120, and the third housing 130 may be sequentially connected to each other via hinges (e.g., the first hinge 101 and the second hinge 102). In an embodiment, the first hinge 101 may be coupled between the first housing 110 and the second housing 120. In an embodiment, the first hinge 101 may include a first hinge device (not shown) that rotatably interconnects the first housing 110 and the second housing 120, and a first hinge housing that covers the first hinge device and is at least partially exposed outside the electronic device 100 between the first housing 110 and the second housing 120. In an embodiment, the second hinge 102 may be coupled between the second housing 120 and the third housing 130. In an embodiment, the second hinge 102 may include a second hinge device (e.g., the second hinge device 730 in FIG. 13A) rotatably interconnecting the second hinge housing 1021 and the third housing 130, and a second hinge housing 1021 that covers the second hinge device and is at least partially exposed outside the electronic device 100 between the second housing 120 and the third housing 130.

In an embodiment, in the electronic device 100, in the state in which two housings are folded to face each other, the remaining housing may rotate to cover the exterior of one of the two housings. For example, the first housing 110 may be folded first toward the upper portion of the second hinge housing 1021 (e.g., the +z direction with reference to FIG. 3) via the first hinge 101 (e.g., a slim hinge). Thereafter, the third housing 130 may be folded toward the second housing 120 via the second hinge 102 (e.g., a wide hinge) to be disposed above the first housing 110 (e.g., the +z direction with reference to FIG. 3). In summary, when the electronic device 100 is in the folded state, the first housing 110 and the second housing 120 face each other, and the second housing 120 may be located between the first housing 110 and the third housing 130. In this case, the third housing 130 may need a rotation radius to accommodate the thickness of the first housing 110 with respect to the second housing 120. The rotation radius between the second housing 120 and the third housing 130 via the second hinge 102 may be greater than the rotation radius between the first housing 110 and the second housing 120 via the first hinge 101. Accordingly, the first hinge 101, which interconnects the first housing 110 and the second housing 120, may be a relatively slim hinge, and the second hinge 102, which interconnects the second housing 120 and the third housing 130, may be a relatively wide hinge.

When the electronic device 100 is unfolded such that the angle between adjacent housings exceeds 180 degrees in the state in which the electronic device 100 is unfolded, or when the adjacent housings are excessively unfolded in the state in which the adjacent are unfolded in parallel to each other, damage to the electronic device 100 may be caused. For example, when the electronic device 100 is unfolded such that the rotation angle between the first housing 110 and the second housing 120 exceeds 180 degrees, or when the electronic device 100 is unfolded such that the rotation angle between the second housing 120 and the third housing 130 exceeds 180 degrees, the electronic device 100 may be damaged. In other words, when the flexible display 140 is bent in excess of 180 degrees, a component of the electronic device 100 including the flexible display 140 may be damaged. Accordingly, the plurality of housings may be designed such that the ends interconnected by the hinges come into contact with each other when the electronic device 100 is in the unfolded state. In other words, when the electronic device 100 is in the unfolded state, the hinge housings of the hinges may be covered by the plurality of housings. For example, when the electronic device 100 is in the unfolded state, the first housing 110 and the second housing 120 may be prevented/blocked from being excessively unfolded as the ends connected to the first hinge 101 are in contact with each other. In this case, when the electronic device 100 is in the unfolded, the exterior of the first hinge 101 (e.g., the first hinge housing) may be covered by the first housing 110 and the second housing 120 to be invisible from the outside of the electronic device 100 or to be only partially exposed. However, due to the folding characteristics of the electronic device 100 described above, the width w12 of the second hinge 102 may be wider than the width w11 of the first hinge 101. In this case, when the electronic device 100 is in the unfolded state, an area, which is not covered by the exterior of the second hinge 102 (e.g., the second hinge housing 1021) by the second housing 120 and the third housing 130, occurs and thus a space 200 or step may be formed between the second housing 120 and the third housing 130. Therefore, due to the step formed between the second housing 120 and the third housing 130, the second housing 120 and the third housing 130 may be folded in excess of 180 degrees, which may cause damage to the electronic device 100. In addition, when external force is applied to the space 200 or the step portion formed between the housings, the electronic device 100 may be damaged.

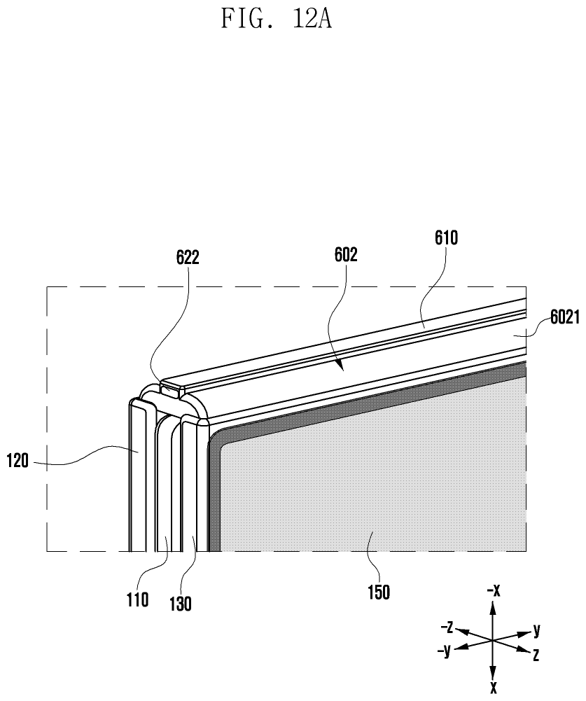

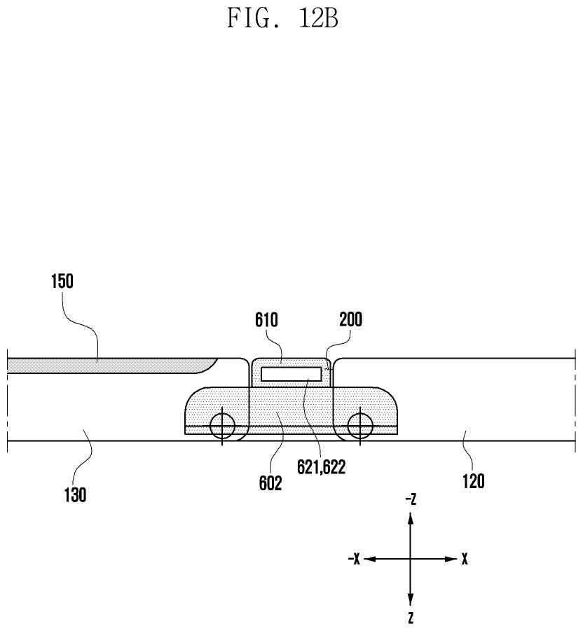

According to an embodiment of the disclosure, since the second housing 120 and the third housing 130 are connected to each other via the second hinge 102 that is wider than the first hinge 101, when the electronic device 100 is in the unfolded state or when the second housing 120 and the third housing 130 are unfolded in parallel to each other, the “space 200” (e.g., step) may be formed between the second housing 120 and the third housing 130. As described above, the space 200 between the second housing 120 and the third housing 130 may be an area in which the second hinge housing 1021 is not covered by the second housing 120 and the third housing 130 when the electronic device 100 is in the unfolded state. In an embodiment, when the electronic device 100 is in the unfolded state, the space 200 between the second housing 120 and the third housing 130 may be a step between the second housing 120 and the second hinge housing 1021 and/or a step (e.g., a height difference) between the third housing 130 and the second hinge housing 1021. In an embodiment, an accessory 300 and/or a stopper (e.g., the stopper 610 in FIG. 12A and/or the stopper 710 in FIG. 13A) may be disposed in the space 200 formed between the second housing 120 and the third housing 130 when the electronic device 100 is in the unfolded state. In an embodiment, referring to FIGS. 4A to 11B, which will be described later, the accessory 300 may be coupled to the second hinge 102 (e.g., the second hinge housing 1021) to be located in the space 200 formed between the second housing 120 and the third housing 130 when the electronic device 100 is in the unfolded state. In an embodiment, referring to FIG. 12A, which will be described later, the second hinge 102 may be a stopper 610. For example, the second hinge housing 1021 of the second hinge 102 may be at least partially disposed in the space 200 formed between the second housing 120 and the third housing 130 when the electronic device 100 is in the unfolded state to function as a stopper. The stopper 610 may prevent and/or block the second housing 120 and the third housing 130 from being excessively unfolded when the second and third housings are unfolded in parallel to each other. For example, when the stopper 610 is to be further unfolded while the second housing 120 and the third housing 130 are unfolded in parallel to each other, one end of the second housing 120 and one end of the third housing 130 are brought into contact with each other, thereby preventing/blocking the second housing 120 and the third housing 130 from being excessively unfolded. In an embodiment, referring to FIGS. 13A to 18C, which will be described later, the stopper 710 may be located in the opening (e.g., the opening 721 in FIG. 13A) in the second hinge housing 1021. The stopper 710 is in contact with the second hinge device and may protrude relative to the opening 721 in the second hinge housing 1021 as the second housing 120 and the third housing 130 rotate. Therefore, when the electronic device 100 is in the unfolded state, the stopper 710 is located in the space 200 formed between the second housing 120 and the third housing 130, thereby preventing/blocking the second housing 120 and the third housing 130 from being unfolded excessively in the state the state in which the second and third housings are unfolded in parallel to each other. A more detailed description of the above-mentioned examples will be provided below.

In an embodiment of the disclosure, it is assumed that the second hinge 102 is wider than the first hinge 101. Accordingly, the description will be made assuming that the accessory 300 and/or the stopper 610 or 710 is coupled to or cooperates with the second hinge 102 to be located between the second housing 120 and the third housing 130. However, the above-mentioned assumption may not limit the various embodiments of the disclosure. For example, when the electronic device 100 is in the unfolded state and a space 200 or a step is formed between the first housing 110 and the second housing 120, an accessory 300 fastening structure and a stopper structure to be described below may be equally applied to the first hinge 101.

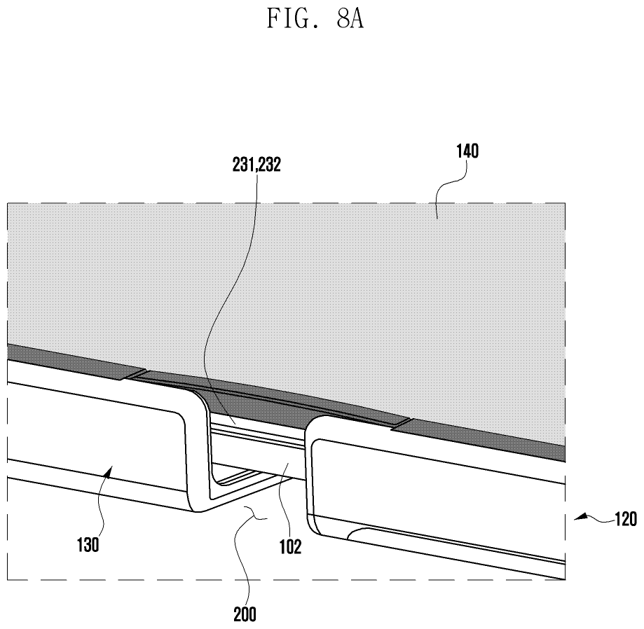

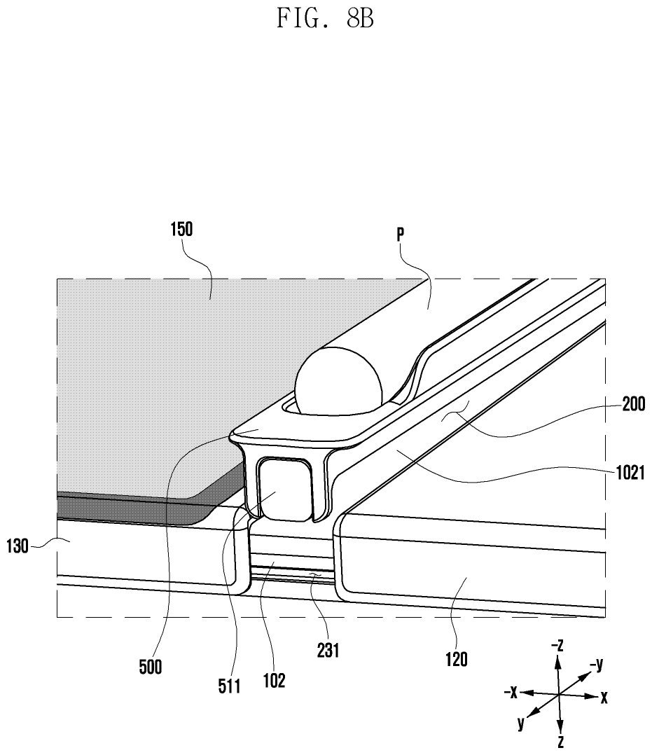

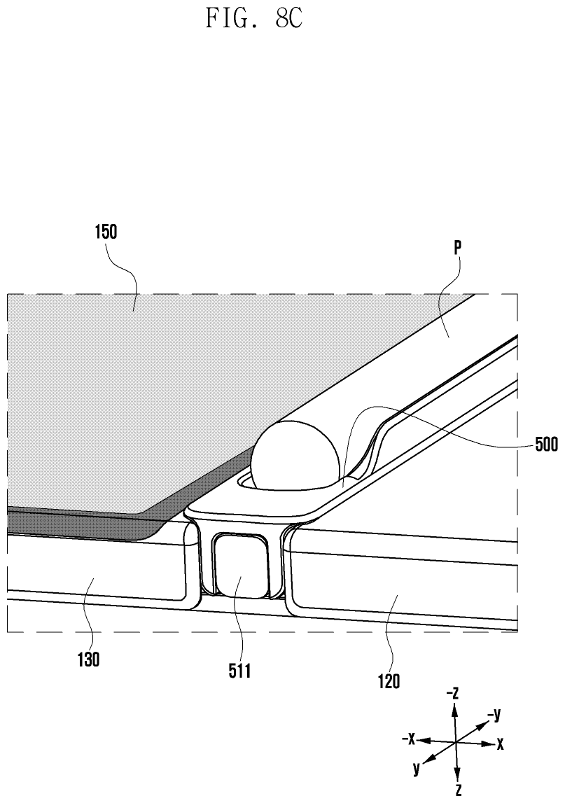

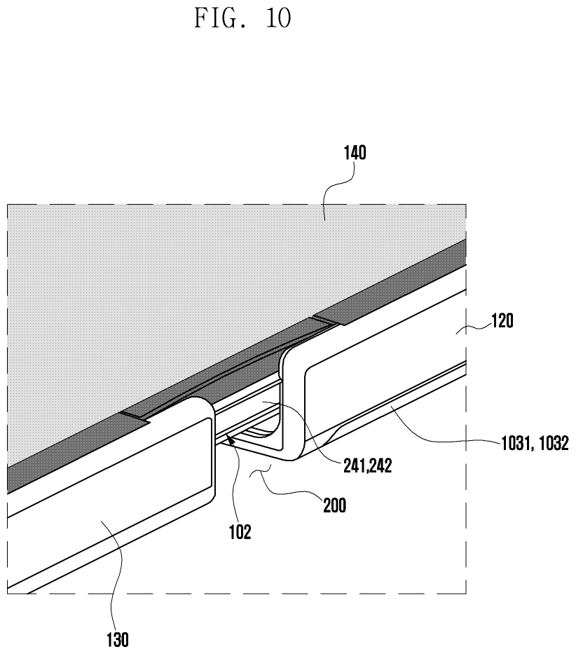

According to an embodiment, as illustrated in FIG. 4A, the second hinge 102 may include a fastening structure that can be fastened to the accessory 300. In an embodiment, the fastening structure may be connected to one component of the accessory 300 to secure the accessory 300 to the second hinge 102. In an embodiment, referring to FIG. 5A, the fastening structure may include a first coupling hole 211 and a second coupling hole 212 into each of which a portion of the accessory 300 is inserted. In an embodiment, referring to FIG. 5C, the fastening structure may include a first locking portion 213 and a second locking portion 214 configured to be fastened to the accessory 300. In addition, the fastening structure may include a first elastic member 215 (e.g., the first elastic member 215 in FIG. 5C), a second elastic member 216 (e.g., the second elastic member 216 in FIG. 5C), a first release hole 221 (e.g., the first release hole 221 in FIG. 5C), a second release hole 222 (e.g., the second release hole 222 in FIG. 5C), a first groove 231 (e.g., the first groove 231 in FIG. 8A), a second groove 232 (e.g., the second groove 232 in FIG. 8A), a first protrusion 241 (e.g., the first protrusion 241 in FIG. 10), and a second protrusion 242 (e.g., the second protrusion 242 in FIG. 10). A detailed description of the above-described components will be provided below.

In an embodiment, referring to FIG. 4A, an accessory 300 may be disposed on the second hinge 102. In an embodiment, the accessory 300 may be a cover accessory 300 configured to cover a portion of the exterior of the second hinge 102 to protect the second hinge 102 from external shock. In an embodiment, the accessory 300 coupled to the second hinge 102 may function as a strap to assist a user in easily holding the electronic device 100. In an embodiment, the accessory 300 may be used to store an electronic component to be used in cooperation with the electronic device 100. For example, the accessory 300 may store an electronic pen P (e.g., a stylus pen) that is connected to the electronic device 100 and enables touch input on the flexible display. Referring to FIG. 4B, the accessory 300 coupled to the second hinge 102 may have a seating groove 301 in which the electronic pen P can be stored.

In an embodiment, referring to FIG. 4B, various types of accessories 300 may be disposed on the second hinge 102. In an embodiment, accessories 300 of various sizes may be fastened to the second hinge 102. For example, the accessory 300 may have a width that can be accommodated in the space 200 formed between the second housing 120 and the third housing 130 when the electronic device 100 is in the unfolded state. In this case, when the electronic device 100 is in the unfolded state, the accessory 300 may be located in the space 200 formed between the second housing 120 and the third housing 130 to prevent/block the second housing 120 and the third housing 130 to be excessively unfolded. In an embodiment, the accessory 300 may have a width wider than the space 200 formed between the second housing 120 and the third housing 130 when the electronic device 100 is in the unfolded state. In this case, when the electronic device 100 is in the unfolded state, only the fasteners (e.g., the first fastener 310 and the second fastener 320) of the accessory 300 may be located in the space 200 formed between the second housing 120 and the third housing 130. The fasteners 310 and 320 of the accessory 300 may be provided at opposite ends of the accessory 300, respectively, and fastened to the second hinge 102. When the electronic device 100 is in the unfolded state, the fasteners of the accessory 300 may be located in the space 200 formed between the second housing 120 and the third housing 130 to prevent/block the second housing 120 and the third housing 130 from being excessively unfolded.

According to an embodiment, as illustrated in FIG. 4C, the accessory 300 may include a first fastener 310 and a second fastener 320 which are fastened to the second hinge 102. In an embodiment, the first fastener 310 may be provided at one end of the accessory 300, and the second fastener 320 may be provided at the other end of the accessory 300. As will be described later, as the first fastener 310 located at one end of the accessory 300 is inserted into the first coupling hole 211 located at one end of the second hinge 102 and the second fastener 320 is inserted into the second coupling hole 212 located at the other end of the second hinge 102, the accessary 300 may be coupled to the second hinge 102.

According to an embodiment, as illustrated in FIGS. 5A to 5D, a coupling structure to which the accessory 300 can be fastened may be provided in the second hinge 102. In an embodiment, the second hinge 102 may include a first coupling hole 211 provided at one end portion 1031 (e.g., the +Y direction with reference to FIG. 5A) and a second coupling hole 212 provided at the other end portion 1032 (e.g., the −Y direction with reference to FIG. 5A). In an embodiment, the first coupling hole 211 and the second coupling hole 212 may be provided in the second hinge housing 1021 that defines the exterior of the second hinge 102. As the first fastener 310 of the accessory 300 is inserted into the first coupling hole 211 and the second fastener 320 of the accessory 300 is inserted into the second coupling hole 212, the second hinge 102 may be coupled with the accessory 300.

In an embodiment, referring to FIGS. 5C and 5D, the first locking portion 213 to be fastened to the first locking hole 311 provided in the first fastener 310 of the accessary 300 may be disposed inside the first coupling hole 211 in the second hinge 102.

In an embodiment, referring to FIG. 5C, a first elastic member 215 (e.g., rubber, urethane, spring) may be disposed below the first locking portion 213 (e.g., in the first direction in FIG. 5C). In an embodiment, the first elastic member 215 may be supported within the second hinge housing 1021 via a component of the second hinge housing 1021 or a component of the second hinge device. As the first fastener 310 of the accessory 300 is inserted into the first coupling hole 211, the first locking portion 213 is pressed by the first fastener 310 to move in the first direction, and may then move in the second direction toward the first locking hole 311 in the first fastener 310 through the elastic restoring force of the first elastic member 215 to be fastened to the first locking hole 311. In an embodiment, referring to FIG. 5C, a second elastic member 216 (e.g., rubber, urethane, spring) may be disposed below the second locking portion 214 (e.g., in the first direction in FIG. 5C). In an embodiment, the second elastic member 216 may be supported within the second hinge housing 1021 via a component of the second hinge housing 1021 or a component of the second hinge device. As the second fastener 320 of the accessory 300 is inserted into the second coupling hole 212, the second locking portion 214 may be pressed by the second fastener 320 to move in the first direction, and may then move in the second direction toward the second locking hole 321 in the second fastener 320 through the elastic restoring force of the second elastic member 216 to be fastened to the second locking hole 321. Accordingly, the accessory 300 may be fixed to the exterior of the second hinge 102 (e.g., the second hinge housing 1021).

In an embodiment, referring to FIG. 5D, an empty space 201 may be provided below the first locking portion 213 (e.g., in the first direction in FIG. 5D). As the first fastener 310 of the accessory 300 is inserted into the first coupling hole 211, the first locking portion 213 may be pressed by the first fastener 310 to move in the first direction toward the empty space 201, and may then move in the second direction toward the first locking hole 311 in the first fastener 310 through the elastic restoring force of the first locking portion 213 itself to be fastened to the first locking hole 311. Similarly, the second locking portion 214 to be fastened to the second locking hole 321 provided in the second fastener 320 of the accessary 300 may be disposed inside the second coupling hole 212 in the second hinge 102. In an embodiment, referring to FIG. 5D, an empty space 201 may be provided below the second locking portion 214 (e.g., in the first direction in FIG. 5D). As the second fastener 320 of the accessory 300 is inserted into the second coupling hole 212, the second locking portion 214 may be pressed by the second fastener 320 to move in the first direction toward the empty space 201, and may then move in the second direction toward the second locking hole 321 in the second fastener 320 through the elastic restoring force of the second locking portion 214 itself to be fastened to the second locking hole 321. Accordingly, the accessory 300 may be fixed to the exterior of the second hinge 102 (e.g., the second hinge housing 1021).

According to an embodiment, the second hinge 102 may include a first release hole 221 which exposes the exterior of the first locking portion 213 and a second release hole 222 which exposes the exterior of the second locking portion 214. In an embodiment, the first release hole 221 and the second release hole 222 may be provided in the second hinge housing 1021. In an embodiment, referring to FIG. 5A, the first release hole 221 and the second release hole 222 may be provided in the second hinge housing 1021 to be located in the z-axis direction of FIG. 5A. In an embodiment, referring to FIGS. 5C and 5D, the first release hole 221 may be provided in a first direction perpendicular to the insertion direction of the first fastener 310 of the accessory 300. The second release hole 222 may be provided in the first direction perpendicular to the insertion direction of the second fastener 320 of the accessory 300. In an embodiment, at least a portion of the first locking portion 213 may face the first release hole 221. In an embodiment, when the first locking portion 213 is pressed in the first direction through the first release hole 311 in the state in which the first locking portion 213 is fastened to the first locking hole 311 in the accessory 300, the first locking hole 311 in the accessory 300 may be separated from the first locking portion 213. Similarly, in an embodiment, at least a portion of the second locking portion 214 may face the second release hole 222. In an embodiment, when the second locking portion 214 is pressed in the first direction through the second release hole 222 in the state in which the second locking portion 214 is fastened to the second locking hole 321 in the accessory 300, the second locking hole 311 in the accessory 300 may be separated from the second locking portion 214. Therefore, in the state in which the accessory 300 is fastened to the second hinge 102, by pressing the first locking portion 213 in the first direction through the first release hole 221 and pressing the second locking portion 214 in the first direction through the second release hole 222, the accessory 300 may be removed from the second hinge housing 1021.

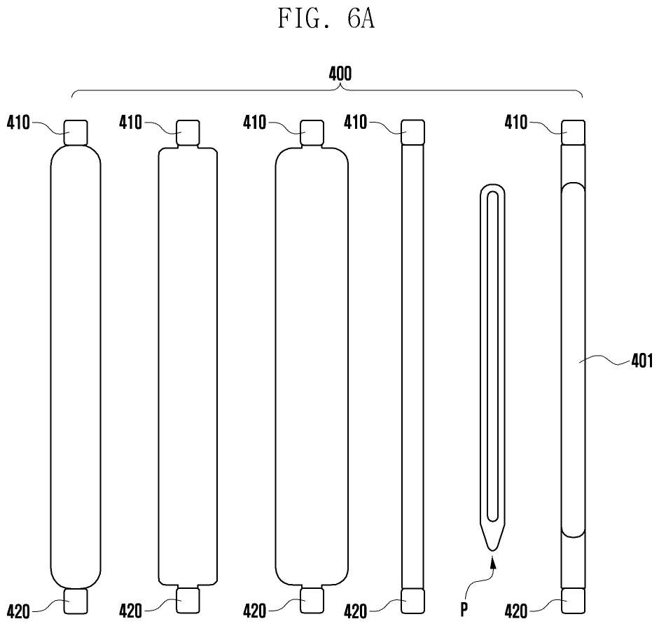

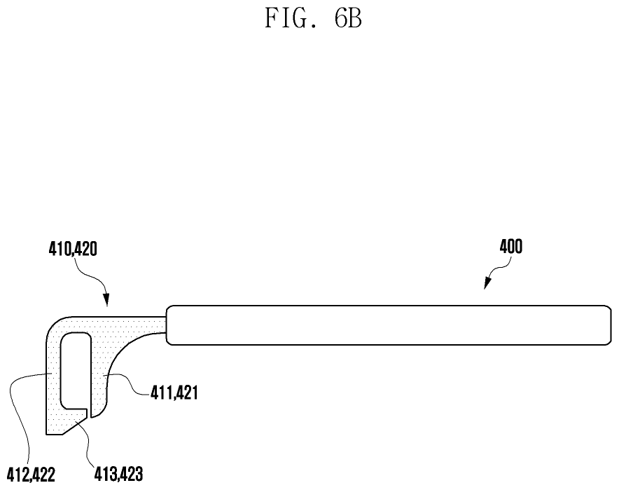

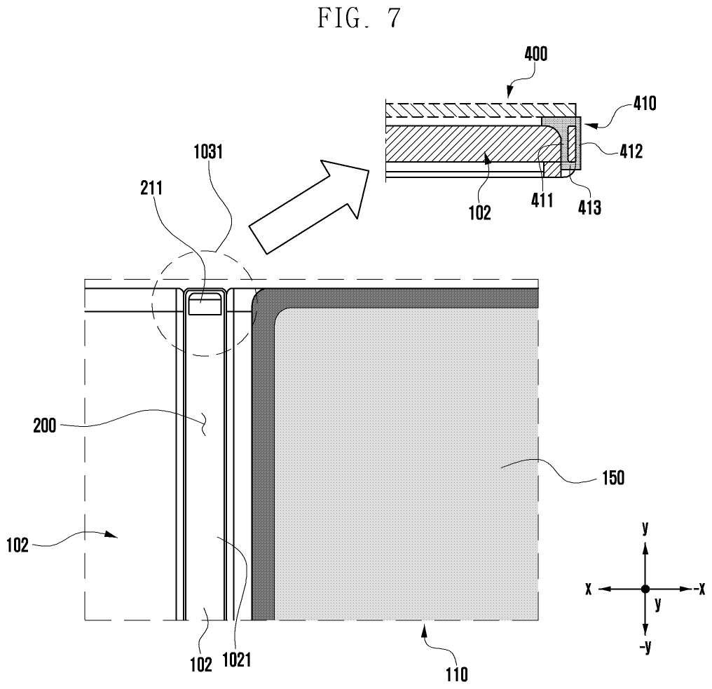

FIG. 6A is a diagram illustrating example front views of various types of accessories to be fastened to the second hinge in a clipping manner, according to various embodiments. FIG. 6B is a diagram illustrating cut portions in a fastener of one of the accessories illustrated in FIG. 6A according to various embodiments. FIG. 7 is a diagram including a cross-sectional view illustrating the state in which the accessory of FIG. 6A is fastened to the second hinge according to various embodiments.

According to an embodiment, as illustrated in FIGS. 6A, 6B, and 7, various types of accessories 400 may be disposed on the second hinge 102. In an embodiment, referring to FIGS. 6A and 6B, a first fastener 410 and a second fastener 420 of an accessory 400 may be fabricated in a clip shape and be fastened to the first coupling hole 211 and the second coupling hole 212 provided in the second hinge housing 1021 of the second hinge 102. In an embodiment, referring to FIG. 6B, the first fastener 410 may include a first cut portion 411 to be inserted into the first coupling hole 211 (e.g., the first coupling hole 211 in FIG. 7) in the second hinge 102, and a second cut portion 412 located outside the second hinge 102 to surround one end portion 1031 of the second hinge 102. The second fastener 420 may include a third cut portion 421 to be inserted into the second coupling hole 212 (e.g., the second coupling hole 212 in FIG. 7) in the second hinge 102, and a fourth cut portion 422 located outside the second hinge 102 to surround the other end portion 1032 of the second hinge 102.

In an embodiment, referring to FIG. 6A, the accessory 400 may be formed in various sizes. In an embodiment, the accessory 400 may have a width that can be accommodated in the space 200 formed between the second housing 120 and the third housing 130 when the electronic device 100 is in the unfolded state. In this case, when the electronic device 100 is in the unfolded state, the accessory 400 may be located in the space 200 formed between the second housing 120 and the third housing 130 to prevent and/or block the second housing 120 and the third housing 130 to be excessively unfolded. In an embodiment, the accessory 400 may have a width wider than the space 200 formed between the second housing 120 and the third housing 130 when the electronic device 100 is in the unfolded state. In this case, when the electronic device 100 is in the unfolded state, only the fasteners (e.g., the first fastener 410 and the second fastener 420) of the accessory 400 may be located in the space 200 formed between the second housing 120 and the third housing 130. The fasteners of the accessory 400 may be provided at opposite ends of the accessory 400, respectively, and fastened to the second hinge 102. When the electronic device 100 is in the unfolded state, the fasteners of the accessory 400 may be located in the space 200 formed between the second housing 120 and the third housing 130 to prevent/block the second housing 120 and the third housing 130 from being excessively unfolded. In an embodiment, the accessory 400 may include a seating groove 401 in which an electronic pen is stored.

According to an embodiment, as illustrated in FIG. 7, a first coupling hole 211 and a second coupling hole 212 may be provided in a second hinge housing 1021 of a second hinge 102. In an embodiment, the first coupling hole 211 and the second coupling hole 212 may be provided in the second hinge housing 1021 in the Z-axis direction of FIG. 7.

In an embodiment, referring to FIG. 6B and FIG. 7 as the first fastener 410 is inserted into the first coupling hole 211 in the second hinge 102 and the second fastener 420 is inserted into the second coupling hole 212 in the second hinge 102, the accessory 400 may be fixed to the second hinge 102. In an embodiment, the first fastener 410 has a first cut portion 411 that may be inserted into the first coupling hole 211, and a second cut portion 412 that may surround a portion of the exterior of the second hinge 102 (e.g., the second hinge housing 1021) outside the first coupling hole 211. In an embodiment, the first cut portion 411 and the second cut portion 412 may fix the accessory 400 to one end portion 1031 of the second hinge 102 while surrounding the end portion that divides the first coupling hole 211 and the exterior of the second hinge 102. In an embodiment, a support 413 provided in the second cut portion 412 may be caught on the exterior of the second hinge 102. The support 413 of the second cut portion 412 may prevent and/or inhibit the accessory 400 from being unintentionally removed from the second hinge 102. In an embodiment, the second fastener 420 has a third cut portion 421 that may be inserted into the second coupling hole 212, and a fourth cut portion 422 that may surround a portion of the exterior of the second hinge 102 (e.g., the second hinge housing 1021) outside the second coupling hole 212. In an embodiment, the third cut portion 421 and the fourth cut portion 422 may fix the accessory 400 to the other end portion 1032 of the second hinge 102 while surrounding the end portion that divides the second coupling hole 212 and the exterior of the second hinge 102. In an embodiment, a support 423 provided in the fourth cut portion 422 may be caught on the exterior of the second hinge 102. The support 423 of the fourth cut portion 422 may prevent and/or avoid the accessory 400 from being unintentionally removed from the second hinge 102.

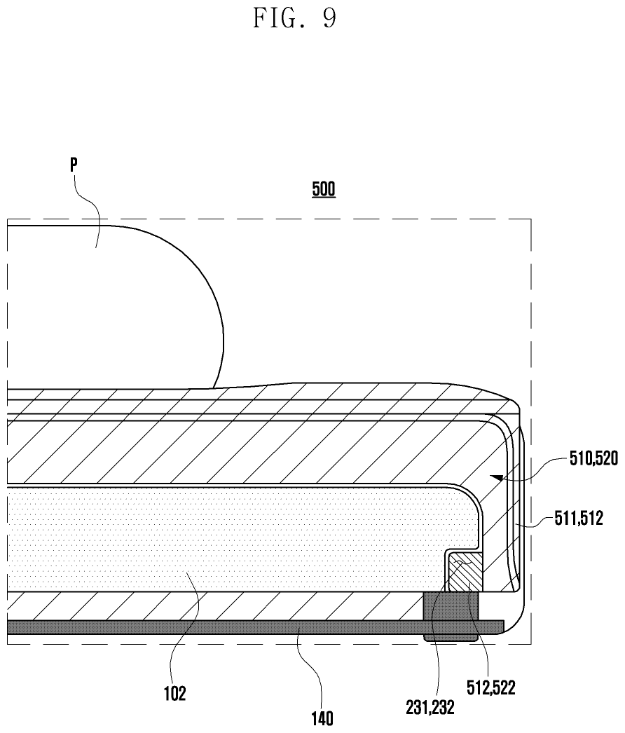

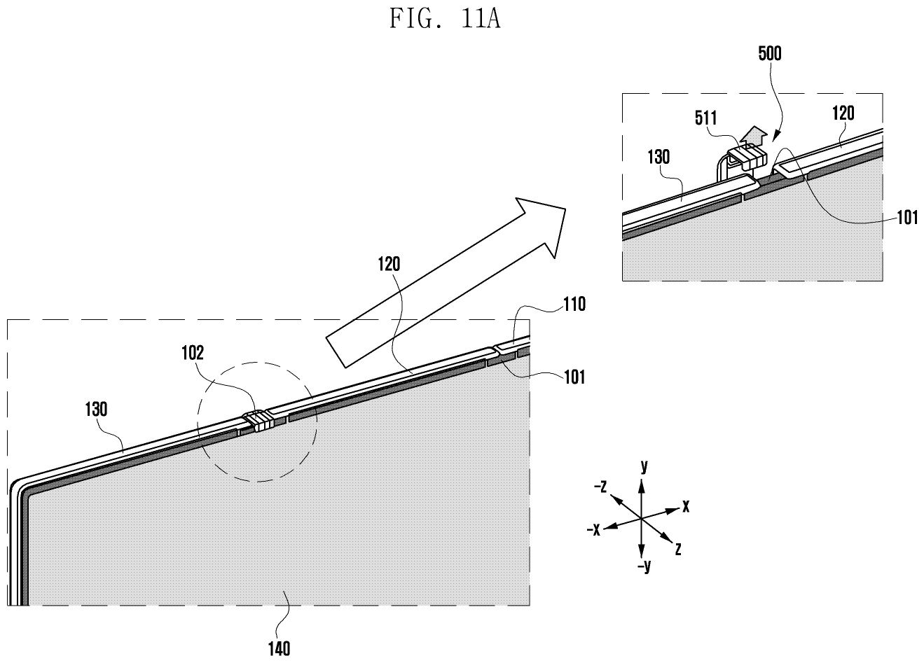

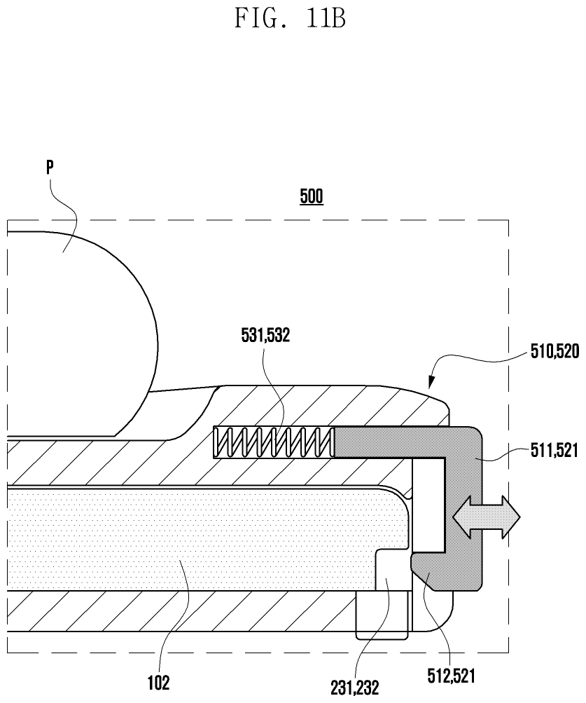

FIG. 8A is a perspective view illustrating the state in which a groove into which a lug of an accessory is inserted is provided in the second hinge, according to various embodiments. FIGS. 8B and 8C are perspective views illustrating an example process in which an accessory is fastened to the second hinge of the electronic device via a hook, according to various embodiments. FIG. 9 is a diagram illustrating a state in which a lug of an accessory is inserted into the groove of the second hinge according to various embodiments. FIG. 10 is a perspective view of the second hinge to which an accessory including a hook is coupled according to various embodiments. FIG. 11A is a diagram illustrating an example process in which an accessory including a hook configured to cooperate with an elastic member is coupled to the second hinge of the electronic device, according to various embodiments. FIG. 11B is a diagram illustrating an accessory including a hook configured to cooperate with an elastic member, according to various embodiments.

According to an embodiment, the accessory 500 may include a first fastener 510 that has a first hook 511 caught on one end portion 1031 of the second hinge 102, and a second fastener 520 that has a second hook 521 caught on the other end portion 1032 of the second hinge 102. In an embodiment, the hooks 511 and 521 may be configured to press the outer surface of the second hinge 102.

In an embodiment, referring to FIG. 8A, the second hinge 102 may include a first groove 231 on the outer surface of one end portion 1031, wherein the first hook 511 of the accessory 500 is fastened to the first groove, and a second groove 232 on the outer surface of the other end portion 1032, wherein the second hook 521 of the accessory 500 is fastened to the second groove. In an embodiment, the first groove 231 may be provided in one end portion 1031 of the second hinge housing 1021, and the second groove 232 may be provided in the other end portion 1032 of the second hinge housing 1021. In an embodiment, referring to FIG. 8B and FIG. 8C, as the first hook 511 presses one end portion 1031 of the second hinge 102 and the second hook 521 presses the other end portion 1032 of the second hinge 102, the accessory 500 may be fixed to the second hinge 102.

According to an embodiment, as illustrated in FIG. 9, a first lug 512 provided on the first hook 511 of the accessory 500 may be inserted into the first groove 231 in the second hinge 102. Likewise, a second lug 522 provided on the second hook 521 of the accessory 500 may be inserted into the second groove 232 in the second hinge 102. In an embodiment, the first lug 512 and the second lug 522 may increase the fixing force of the accessory 500 with respect to the second hinge 102.

According to an embodiment, as illustrated in FIG. 10, the second hinge 102 may include a first protrusion 241 on one end portion 1031 and a second protrusion 242 on the other end portion 1032. In an embodiment, the first protrusion 241 may be provided in one end portion 1031 of the second hinge housing 1021, and the second protrusion 242 may be provided in the other end portion 1032 of the second hinge housing 1021. In an embodiment, referring to FIG. 10, the first protrusion 241 and the second protrusion 242 may be areas that protrude relatively from adjacent mechanical elements. In an embodiment, the first lug 512 of the accessory 500 may be caught on the first protrusion 241 of the second hinge 102, and the second lug 522 may be caught on the second protrusion 242 of the second hinge 102. Accordingly, the accessory 500 may be fixed to the second hinge 102.

According to an embodiment, as illustrated in FIGS. 11A and 11B, the first hook 511 of the accessory 500 may be connected to a third elastic member 531 (e.g., a spring). In an embodiment, the first hook 511 moves in the direction in which external force is applied, and may be returned by the elastic restoring force of the third elastic member 531 when the external force is removed. Likewise, the second hook 521 of the accessory 500 may be connected to the fourth elastic member 532 (e.g., a spring). In an embodiment, the second hook 521 moves in the direction in which external force is applied, and may be returned by the elastic restoring force of the fourth elastic member 532 when the external force is removed. In an embodiment, the first hook 511 and the second hook 521 may be fastened to the second hinge 102 after moving away from the main body of the accessory 500 so that the accessory 500 can be easily fastened to the second hinge 102. Thereafter, the first hook 511 may be in close contact with one end of the second hinge 102 by the elastic restoring force of the third elastic member 531. The second hook 521 may be in close contact with the other end of the second hinge 102 by the elastic restoring force of the fourth elastic member 532.

In an embodiment, referring to FIG. 11B, the fixing force of the first hook 511 of the accessory 500 on the one end of the second hinge 102 may be increased by the elastic restoring force of the third elastic member 531 applied in the state in which the first hook 511 is fastened to the one end of the second hinge 102. The fixing force of the second hook 521 of the accessory 500 on the other end of the second hinge 102 may be increased by the elastic restoring force of the fourth elastic member 532 applied in the state in which the second hook 521 is fastened to the other end of the second hinge 102.

FIG. 12A is a perspective view of a second hinge including a stopper, according to various embodiments. FIG. 12B is a diagram illustrating the state in which the stopper is located in a space formed between the second housing and the third housing when the electronic device is in the unfolded state, according to various embodiments.

According to an embodiment, as illustrated in FIGS. 12A and 12B, a second hinge 602 (e.g., the second hinge 102 in FIG. 1A) may include a stopper 610 located in the space 200 that is formed between the second housing 120 and the third housing 130 as the electronic device 100 is unfolded. In an embodiment, the stopper 610 may be at least a portion of the second hinge housing 6021 that defines the exterior of the second hinge 602. In an embodiment, the stopper 610 may be a portion of the second hinge housing located at a step between the second housing 120 and the third housing 130. For example, the stopper 610 may be a portion of the second hinge housing 6021 that protrudes in the −z-axis direction with reference to FIG. 12B. In an embodiment, the stopper 610 may form a substantially flat surface with the second housing 120 and the third housing 130 when the second housing 120 and the third housing 130 are unfolded in parallel to each other. In an embodiment, when the second housing 120 and the third housing 130 are to be further unfolded (e.g., when the second housing 120 and the third housing 130 are to be unfolded such that the rotation angle therebetween exceeds 180 degrees) due to external force applied thereto in the state in which the second housing 120 and the third housing 130 are unfolded in substantially parallel to each other, the second housing and the third housing may not be further unfolded since one end of the second housing 120 and one end of the third housing 130 are brought into contact with the stopper 610. Accordingly, the stopper 610 may prevent/block the second housing 120 and the third housing 130 from being excessively unfolded by the space 200 or step formed between the second housing 120 and the third housing 130 in the state in which the second housing 120 and the third housing 130 are unfolded in parallel to each other.

According to an embodiment, an accessory (e.g., the accessory 300 in FIG. 4B, the accessory 400 in FIG. 6A, or the accessory 500 in FIG. 8B) may be disposed on one surface of the stopper 610. In an embodiment, the accessory fastening structure of the second hinge 602 described above with reference to FIGS. 5A to 11B may be equally applied to the stopper 610, which is a component of the second hinge 602. For example, referring to FIGS. 12A and 12B, the stopper 610 may include a first coupling hole 621 and a second coupling hole 622. In an embodiment, the first coupling hole 621 may be provided in one end portion of the stopper 610 (e.g., the portion located in the +y-axis direction with reference to FIG. 12A), and the second coupling hole 622 may be provided in the other end portion of the stopper 610 (e.g., the portion located in the −y-axis direction with reference to FIG. 12A). In an embodiment, as the first fastener 310, 410, or 510 is inserted into the first coupling hole 621 and the second fastener 320, 420, or 520 is inserted into the second coupling hole 622, the accessory 300, 400, or 500 may be fixed to the stopper 610. In an embodiment, as described above with reference to FIGS. 5A to 5D, as the first locking groove 311 of the first fastener 310 is fastened to the first locking portion 213 located inside the stopper 610, and the second locking groove 321 of the second fastener 320 is fastened to the second locking portion 214 located inside the stopper 610, the accessory 300 may be fixed to the stopper 610. In an embodiment, as described above with reference to FIGS. 6A to 7, as the first cut portion 411 and the second cut portion 412 of the first fastener 410 surround the end portion that divides the coupling hole 621 and the exterior of the stopper 610, the accessory 400 may be fixed to one end portion of the stopper 610. In addition, as the third cut portion 421 and the fourth cut portion 422 of the second fastener 420 surround the end portion that divide the second coupling hole 622 and the exterior of the stopper 610, the accessary 400 may be fixed to the one end portion of the stopper 610. In an embodiment, as illustrated in FIGS. 8A to 11B, the accessory 500 may be fixed to one end portion and the other end portion of the stopper 610 via the hooks 511 and 521.

FIG. 13A is a diagram illustrating a plan view of a stopper located in an opening provided in a hinge housing, according to various embodiments. FIG. 13B is a cross-sectional view of a second hinge taken along line 13a-13a of FIG. 13A according to various embodiments.

According to an embodiment, as illustrated in FIGS. 13A and 13B, a second hinge 702 (e.g., the second hinge 102 in FIG. 5A and/or the second hinge 602 in FIG. 12A) may include a second hinge device 730 coupled to the second housing 120 and the third housing 130, and a second hinge housing 720 that covers a portion of the second hinge device 730 and at least partially defines the exterior of the electronic device 100. In an embodiment, the second hinge device 730 and the first hinge device of the first hinge (e.g., the first hinge 101 in FIG. 1A) may be assembly modules with substantially the same configuration except that the sizes of components thereof are different. The configuration of the second hinge device 730, which will be described below, may be the same as that of the first hinge device.

In an embodiment, the second hinge device 730 may include a bracket (not illustrated), a first rotator 741, a second rotator 742, a first arm (not illustrated), and a second arm (not illustrated). In an embodiment, the first arm may be a component of the first rotator 741 and the second arm may be a component of the second rotator 742. The above-described components are merely examples, and at least one of the above-described components may be omitted or other components may be added as needed. In an embodiment, the bracket may be the body of the second hinge device 730, on which components of the second hinge device 730 may be coupled to each other. The components of the second hinge device 730 may be disposed around the bracket and may be coupled to each other or installed to cooperate with each other. The first rotator 741 and the second rotator 742 may rotate about the center of the bracket, and the first arm connected to the first rotator 741 and the second arm connected to the second rotator 742 may rotate. In an embodiment, the center of the bracket may be the rotation center of the second hinge device 730. Accordingly, the bracket may be disposed on the second housing 120 and the third housing 130 such that the center of the bracket coincides with the rotation centers of the second housing 120 and the third housing 130. In an embodiment, the first rotator 741 may be connected to the second housing 120, and the second rotator 742 may be connected to the third housing 130. In an embodiment, the first rotator 741 may have a first rotation part 743 that is inserted into a first rail (not illustrated), which is provided on the bracket, to be rotatable about the bracket. The second rotator 742 may have a second rotation part 744 that is inserted into a second rail (not illustrated), which is provided on the bracket, to be rotatable about the bracket. In an embodiment, the second housing 120 and the third housing 130 may be folded or unfolded as the first rotator 741 and the second rotator 742 rotate about the bracket.

According to an embodiment, as illustrated in FIGS. 13A and 13B, the second hinge 702 may include a stopper 710. In an embodiment, at least a portion of the stopper 710 may be located in an opening 721 provided in the second hinge housing 720. In an embodiment, the stopper 710 may extend along the length direction of the second hinge housing 720 (e.g., the y-axis direction in FIG. 13A). In an embodiment, the stopper 710 may move relative to the opening 721 of the second hinge housing 720 in cooperation with the second hinge device 730. For example, while the stopper 710 is disposed inside the second hinge housing 720, the stopper 710 may move relative to the opening 721 in the second hinge housing 720 in response to the rotation action of the first rotator 741 and the second rotator 742 of the second hinge device 730.

In an embodiment, referring to FIG. 13B, the stopper 710 may include a protrusion 711 that moves relative to the opening 721 in the second hinge housing 720 and a support 712 that is in contact with the second hinge device 730. In an embodiment, when the electronic device 100 is in the folded state, the protrusion 711 of the stopper 710 may be located in the opening 721 of the second hinge housing 720 so as to be substantially parallel with one surface of the second hinge housing 720. Thereafter, as the second housing 120 and the third housing 130 are switched from the folded state to the unfolded state, the protrusion 711 of the stopper 710 protrudes with respect to the opening 721 of the second hinge housing 720. The protrusion 711 of the stopper 710 may be located in the space 200 formed between the second housing 120 and the third housing 130 in the state in which the second housing 120 and the third housing 130 are unfolded in substantially parallel to each other. In an embodiment, the protrusion 711 of the stopper 710 may form a substantially flat surface with the second housing 120 and the third housing 130 when the second housing 120 and the third housing 130 are unfolded in parallel to each other. In an embodiment, when the second housing 120 and the third housing 130 are to be further unfolded (e.g., when the second housing 120 and the third housing 130 are to be unfolded in excess of 180 degrees) due to external force applied thereto in the state in which the second housing 120 and the third housing 130 are unfolded in substantially parallel to each other, the second housing and the third housing may not be further unfolded since one end of the second housing 120 and one end of the third housing 130 are brought into contact with the stopper 710. Accordingly, the protrusion 711 of the stopper 710 may prevent/block the second housing 120 and the third housing 130 from being excessively unfolded by the space 200 or step formed between the second housing 120 and the third housing 130 in the state in which the second housing 120 and the third housing 130 are unfolded in parallel to each other.

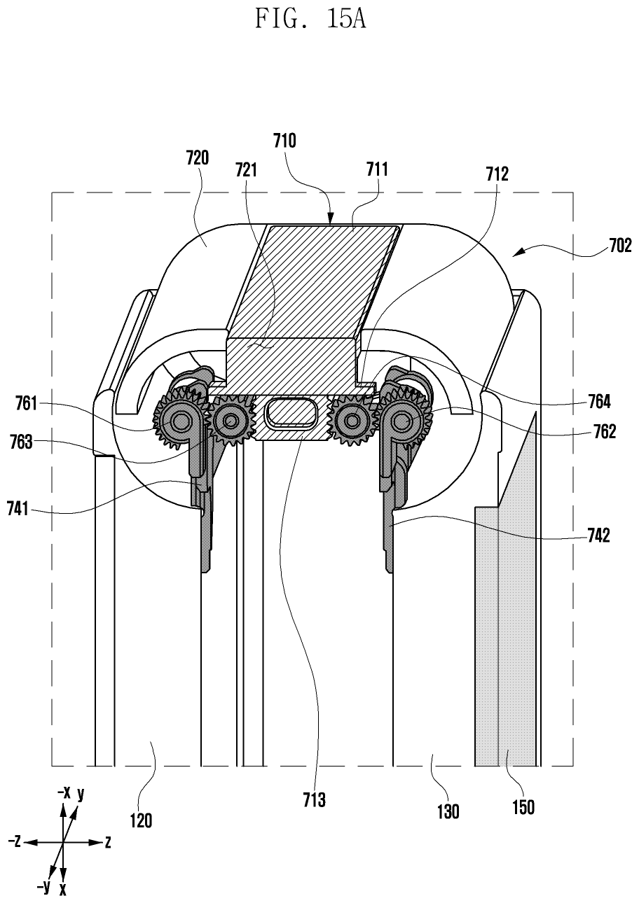

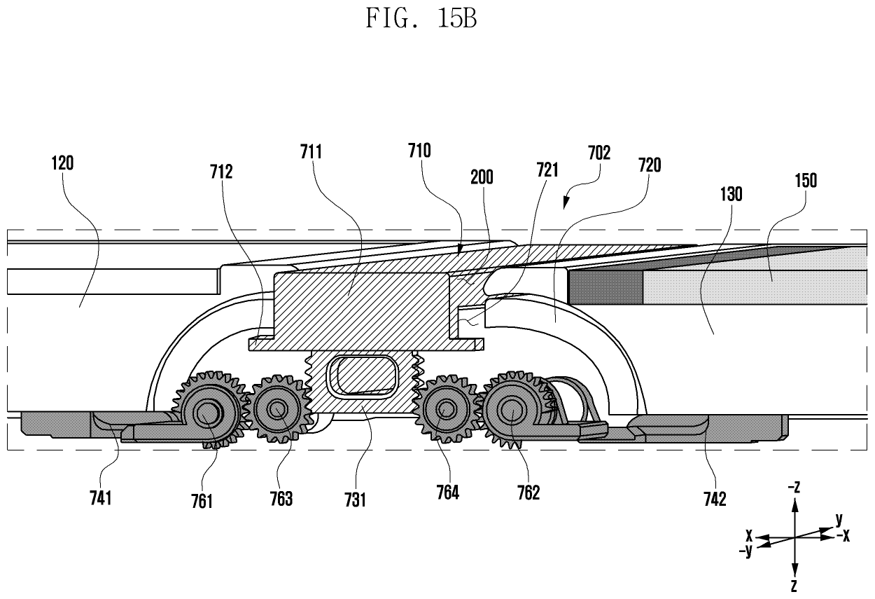

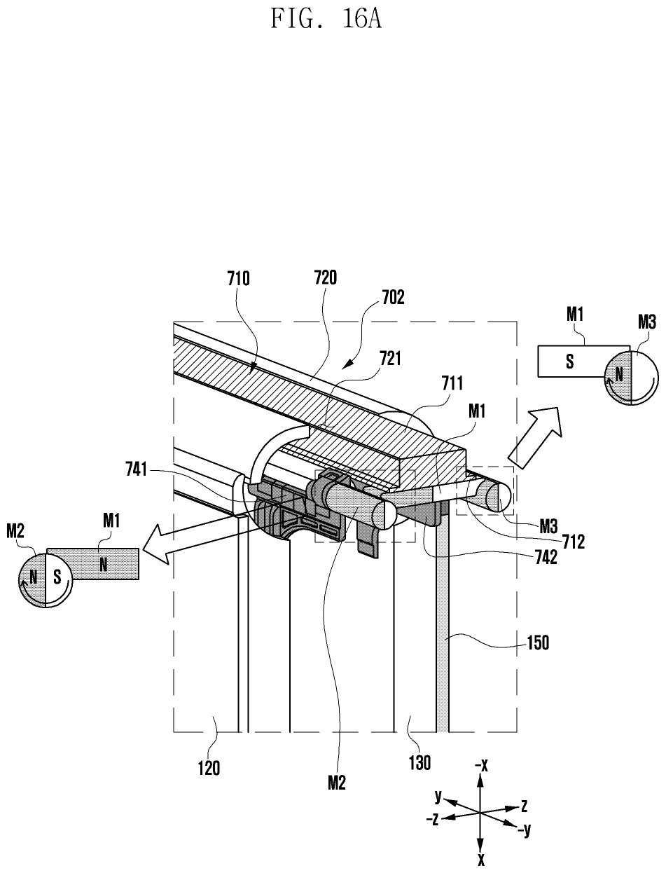

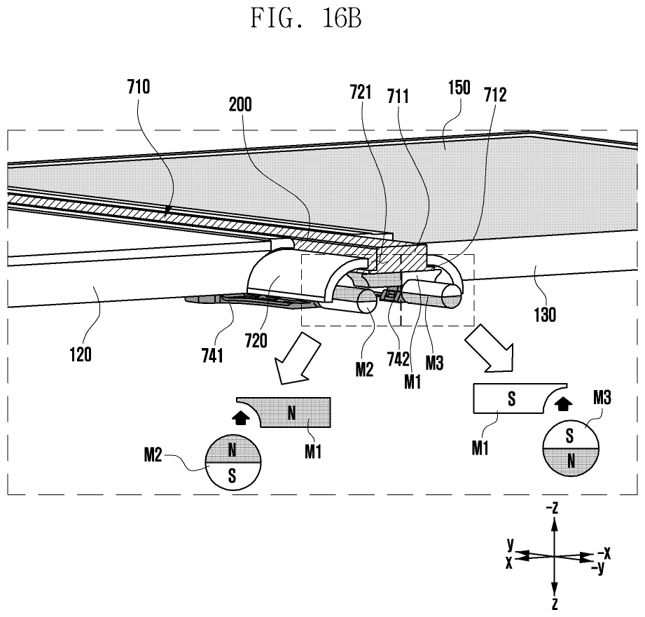

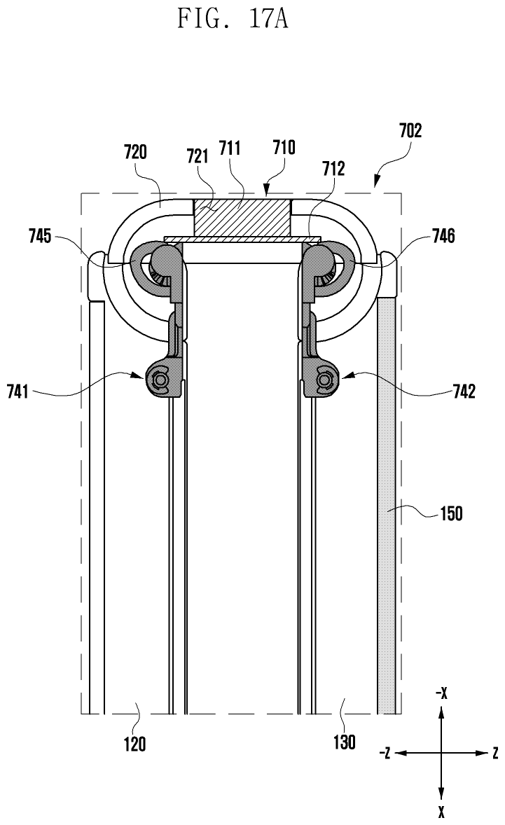

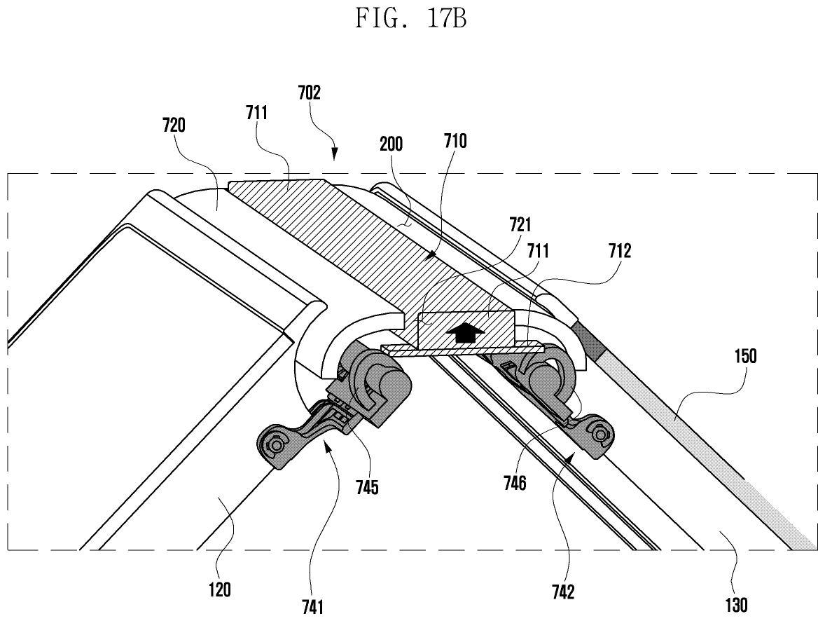

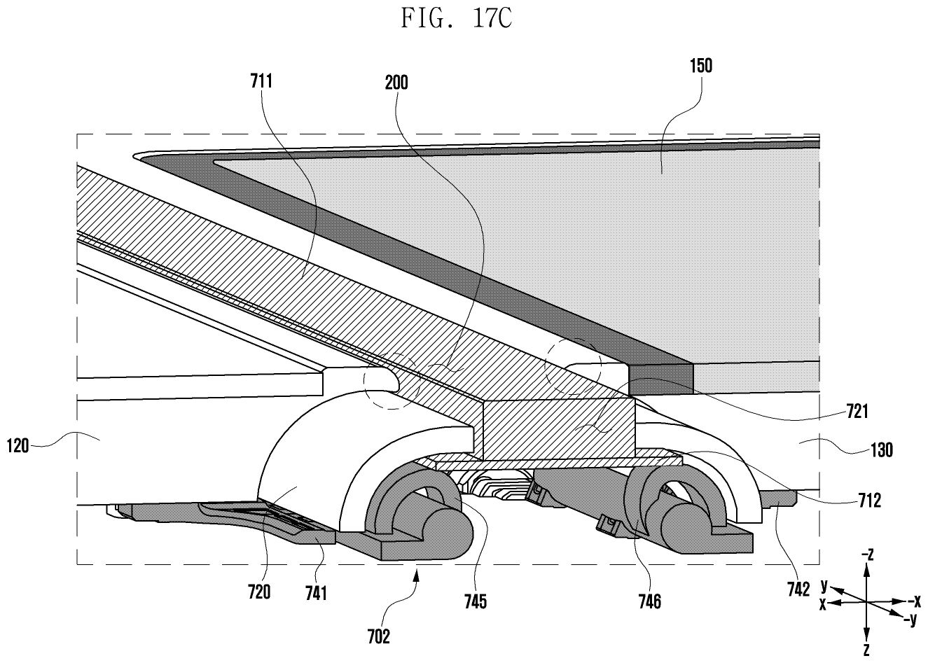

According to an embodiment, as described above, the stopper 710 may be moved with respect to the opening in the second hinge housing 720 in conjunction with the rotation operation of the second hinge device 730 performed in response to the folding operation of the second housing 120 and the third housing 130. In an embodiment, the stopper 710 may cooperate with the second hinge device 730 in various ways. In an embodiment, as the support 712 is brought into contact with a component of the second hinge device 730, the stopper 710 may be moved with respect to the opening 721 in the second housing 120 in conjunction with the rotation operation of the second hinge device 730. In addition, the stopper 710 may be moved with respect to the opening 721 in the second hinge housing 720 by cooperating via the second hinge device 730 through gears (e.g., the first gear 761, the second gear 762, the rack gear 713, the first pinion gear 763, and/or the second pinion gear 764 in FIG. 15A), cooperating with the second hinge device 730 via magnets (e.g., the first magnet M1, the second magnet M2, and/or the third magnet M3 in FIG. 16A), or cooperating with components of the second hinge device 730 (e.g., the first cam 745 and the second cam 346 in FIG. 17A).

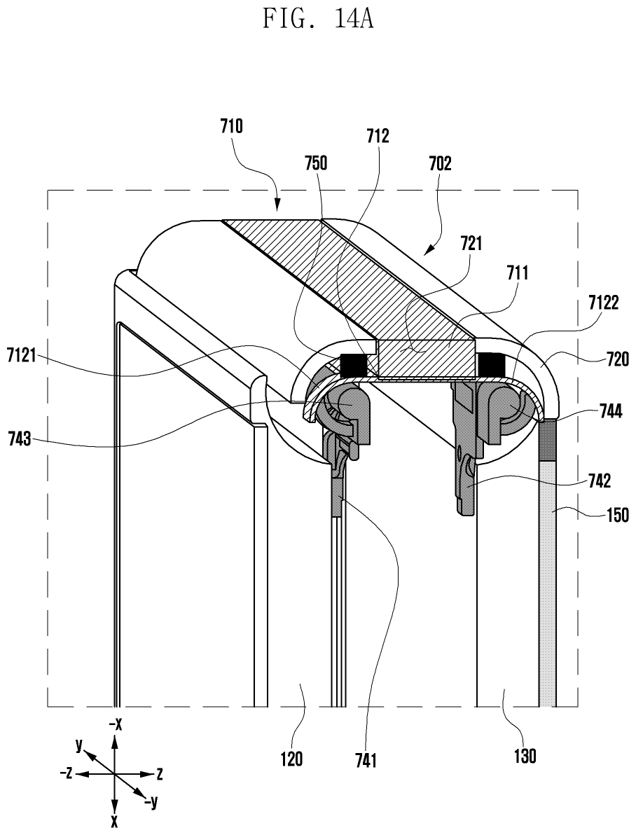

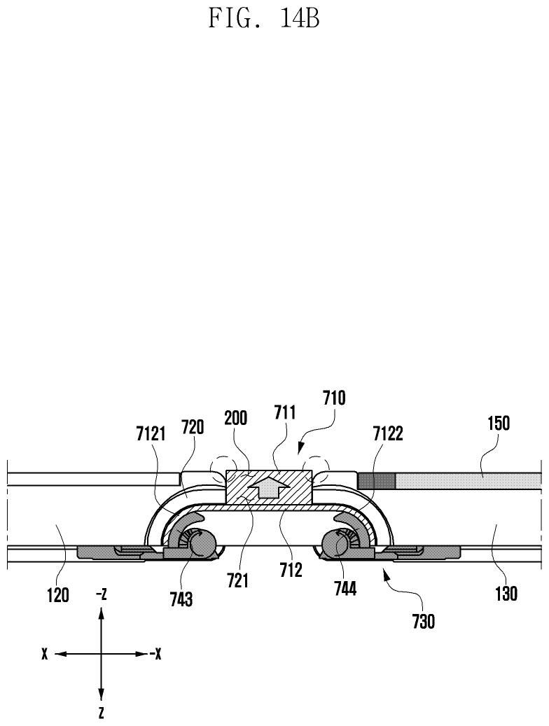

FIGS. 14A and 14B include a perspective and cross-sectional views illustrating an example process in which a stopper moves relative to a hinge housing in cooperation with a rotation part of a hinge device, according to various embodiments.

According to an embodiment, as illustrated in FIGS. 14A and 14B, one surface of the support 712 of the stopper 710 may be brought into contact with the first rotator 741 and the second rotator 742 of the second hinge device 730. In an embodiment, the support 712 of the stopper 710 may be brought into contact with the first rotation part 743 of the first rotator 741 and the second rotation part 744 of the second rotator 742. In an embodiment, when the second housing 120 and the third housing 130 are switched from the folded state to the unfolded state, the stopper 710 may move in the −z-axis direction with reference to FIG. 14B and protrude with respect to the opening 721 in the second hinge housing 720 in conjunction with the rotation operation of the first rotation part 743 and the second rotation part 744 relative to the bracket.

In an embodiment, referring to FIG. 14A, an elastic member 750 may be disposed between the hinge housing and the support 712 of the stopper 710. In an embodiment, the elastic member 750 may prevent/block the support 712 of the stopper 710 from colliding with the second hinge housing 720.

In an embodiment, referring to FIGS. 14A and 14B, the support 712 may include a first bent portion 7121 that comes into contact with the first rotation part 743 of the first rotator 741, and a second bent portion 7122 that comes into contact with the second rotation part 744 of the second rotator 742. In an embodiment, the first bent portion 7121 may have a radius of curvature that comes into contact with the first rotation part 743. The second bent portion 7122 may have a radius of curvature that comes into contact with the second rotation part 744. In an embodiment, the first bent portion 7121 may have the same radius of curvature as the first rotation part 743. In an embodiment, the second bent portion 7122 may have the same radius of curvature as the second rotation part 744. In addition, the first bent portion 7121 and the second bent portion 7122 may have various radii of curvature to be in contact with the first rotation part 743 and the second rotation part 744, respectively. Therefore, when the second housing 120 and the third housing 130 are switched from the folded state to the unfolded state, the support 712 of the stopper 710 may be brought into contact with the first rotation part 743 and the second rotation part 744 and be moved in the −z-axis direction with reference to FIG. 14B. Accordingly, the protrusion 711 of the stopper 710 may protrude with respect to the opening 721 of the second hinge housing 720, and be located in the space 200 formed when the second housing 120 and the third housing 130 are unfolded. In an embodiment, the protrusion 711 of the stopper 710 may protrude with respect to the opening 721 in the second hinge housing 720 to form a substantially flat surface together with the second housing 120 and the third housing 130 in the state in which the second housing 120 and the third housing 130 are unfolded in parallel to each other. In an embodiment, when the second housing 120 and the third housing 130 are to be further unfolded (e.g., when the second housing 120 and the third housing 130 are to be unfolded in excess of 180 degrees) due to external force applied thereto in the state in which the second housing 120 and the third housing 130 are unfolded in substantially parallel to each other, the second housing and the third housing may not be further unfolded since one end of the second housing 120 and one end of the third housing 130 are brought into contact with the stopper 710. Accordingly, the stopper 710 may prevent/block the second housing 120 and the third housing 130 from being excessively unfolded by the space 200 or step formed between the second housing 120 and the third housing 130 in the state in which the second housing 120 and the third housing 130 are unfolded in parallel to each other.

In the foregoing description, it has been described that the stopper 710 is brought into contact with the first rotator 741 and the second rotator 742 and moves with respect to the opening 721 in the second hinge housing 720, but is not limited thereto. In an embodiment, the stopper 710 may be brought into contact with a component of the second hinge device 730 in various ranges that can be implemented by a person ordinarily skilled in the art and protrude with respect to the opening 712 in the second hinge housing 720 in response to the rotation operation of the second hinge device 730.

FIGS. 15A and 15B include a perspective view and a diagram illustrating an example process in which a stopper moves relative to a hinge housing in cooperation with a hinge device via gears, according to various embodiments.

According to an embodiment, as illustrated in FIGS. 15A and 15B, the stopper 710 may cooperate with the second hinge device 730 via gears. In an embodiment, the stopper 710 may include a rack gear 713 extending from the support 712. In an embodiment, the rack gear 713 may cooperate with gears of the second hinge device 730. In an embodiment, the second hinge device 730 may include gears (e.g., a first gear 761 and a second gear 762) configured to cooperate with the rack gear 713. In an embodiment, gears may be provided in components of the second hinge device 730. For example, the first rotator 741 may include the first gear 761 configured to cooperate with the rack gear 713 of the stopper 710. The second rotator 742 may include the second gear 762 configured to cooperate with the rack gear 713 of the stopper 710. In an embodiment, the first gear 761 and the second gear 762 may be in direct contact with the rack gear 713 of the stopper 710. In an embodiment, the stopper 710 may cooperate with the first rotator 741 and the second rotator 742 via gears and move with respect to the opening 721 in the second hinge housing 720 in response to the rotation of the first rotator 741 and the second rotator 742. In an embodiment, the protrusion 711 of the stopper 710 may protrude with respect to the opening 721 in the second hinge housing 720 to form a substantially flat surface together with the second housing 120 and the third housing 130 in the state in which the second housing 120 and the third housing 130 are unfolded in parallel to each other. In an embodiment, when the second housing 120 and the third housing 130 are to be further unfolded (e.g., when the second housing 120 and the third housing 130 are to be unfolded in excess of 180 degrees) due to external force applied thereto in the state in which the second housing 120 and the third housing 130 are unfolded in substantially parallel to each other, the second housing and the third housing may not be further unfolded since one end of the second housing 120 and one end of the third housing 130 are brought into contact with the stopper 710. Accordingly, in the state in which the second housing 120 and the third housing 130 are unfolded in substantially parallel to each other, the protrusion 711 of the stopper 710 may be located in the space 200 between the second housing 120 and the third housing 130 to prevent/block the second housing 120 and the third housing 130 from being excessively unfolded due to the space 200 or step between the second housing 120 and the third housing 130.

In an embodiment, referring to FIGS. 12A and 12B, the second hinge device 730 may include at least one first pinion gear 763 configured to cooperate with the first gear 761 of the first rotator 741 and the rack gear 713 of the stopper 710, and at least one second pinion gear 764 configured to cooperate with the second gear 762 of the second rotator 742 and the rack gear 713 of the stopper 710. In an embodiment, the rotation directions of the first gear 761 and the first pinion gear 763 may be opposite to each other, and the rotation directions of the second gear 762 and the second pinion gear 764 may be opposite to each other. Since one surface of the rack gear 713 may cooperate with the first gear 761 of the first rotator 741 via the first pinion gear 763, the other surface of the rack gear 713 may cooperate with the second gear 762 of the second rotator 742 via the second pinion gear 764, the stopper 710 may protrude with respect to the opening 721 in the second housing 120 in response to the rotation operation of the first rotator 741 and the second rotator 742.

In the foregoing description, it has been described that the first gear 761 is provided on the first rotator 741, and the second gear 762 is provided on the second rotator 742, but the disclosure may not be limited thereto. In an embodiment, the first gear 761 and the second gear 762 may be provided in a component of the second hinge device 730 in a variety of ways that can be implemented by a person ordinarily skilled in the art. For example, the first gear 761 may be provided on a first arm connected to the first rotator 741, and the second gear 762 may be provided on a second arm connected to the second rotator 742.

FIGS. 16A and 16B are perspective views illustrating an example process in which a stopper moves relative to a hinge housing in cooperation with a hinge device via magnets, according to various embodiments.

According to an embodiment, as illustrated in FIGS. 16A and 16B, the stopper 710 may cooperate with the second hinge device 730 via magnets. In an embodiment, a first magnet M1 may be disposed on one surface of the support 712 of the stopper 710 facing the second hinge device 730. In an embodiment, the second hinge device 730 may include a second magnet M2 and a third magnet M3 disposed adjacent to the first magnet M1. In an embodiment, the second magnet M2 may be disposed in the first hinge device to be located on a first rotation axis of the second housing 120. In an embodiment, the first rotation axis may be a virtual axis around which the second housing 120 rotates via the second hinge 702 (e.g., the second hinge 102 in FIG. 5A and/or the second hinge 602 in FIG. 12A). In an embodiment, the second magnet M2 may be disposed on the first rotator 741 or the first arm. In addition, the second magnet M2 may be disposed on various components of the second hinge device 730. In an embodiment, the third magnet M3 may be disposed on the second hinge device 730 to be located on a second rotation axis of the third housing 130. In an embodiment, the second rotation axis may be a virtual axis around which the third housing 130 rotates via the second hinge 702. In an embodiment, the third magnet M3 may be disposed on the second rotator 742 or the second arm. In addition, the third magnet M3 may be disposed on various components of the second hinge device 730.

In an embodiment, referring to FIGS. 16A and 16B, the second magnet M2 may rotate with respect to the first magnet M1 based on the switching of the second housing 120 and the third housing 130 from the folded state to the unfolded state. The third magnet M3 may rotate with respect to the first magnet M1 based on the switching of the second housing 120 and the third housing 130 from the folded state to the unfolded state. In an embodiment, when the second housing 120 and the third housing 130 are in the unfolded state, repulsive force may be applied between the first magnet M1 and the second magnet M2 and the first magnet M1 and the third magnet M3. For example, when the second housing 120 and the third housing 130 are in the folded state, the second magnet M2 and the first magnet M1 may be positioned such that their different poles are adjacent to each other, and the third magnet M3 and the first magnet M1 may be positioned such that their different poles are adjacent to each other. When the second housing 120 and the third housing 130 are in the unfolded state, the second magnet M2 and the first magnet M1 may be positioned such that their same poles are adjacent to each other, and the third magnet M3 and the first magnet M1 may be positioned such that their same poles are adjacent to each other. As the second housing 120 and the third housing 130 are switched from the folded state to the unfolded state, a repulsive force may be applied between the first magnet M1 disposed on the support 712 of the stopper 710 and the second magnet M2 and the third magnet M3 disposed on the second hinge device 730 so that the stopper 710 can move in the −z-axis direction with reference to FIG. 16B. In an embodiment, the protrusion 711 of the stopper 710 may protrude with respect to the opening 721 in the second housing 720 to form a substantially flat surface together with the second housing 120 and the third housing 130 in the state in which the second housing 120 and the third housing 130 are unfolded in parallel to each other. In an embodiment, when the second housing 120 and the third housing 130 are to be further unfolded (e.g., when the second housing 120 and the third housing 130 are to be unfolded in excess of 180 degrees) due to external force applied thereto in the state in which the second housing 120 and the third housing 130 are unfolded in substantially parallel to each other, the second housing and the third housing may not be further unfolded since one end of the second housing 120 and one end of the third housing 130 are brought into contact with the stopper 710. Accordingly, in the state in which the second housing 120 and the third housing 130 are unfolded in substantially parallel to each other, the protrusion 711 of the stopper 710 may be located in the space 200 between the second housing 120 and the third housing 130 to prevent/block the second housing 120 and the third housing 130 from being excessively unfolded due to the space 200 or step between the second housing 120 and the third housing 130.

FIGS. 17A, 17B and 17C include a diagram and perspective views illustrating an example process in which a stopper 710 moves with respect to a hinge housing in cooperation with cams of a hinge device, according to various embodiments.

According to an embodiment, as illustrated in FIGS. 17A, 17B and 17C (which may be referred to as FIGS. 17A to 17C), one surface of a support 712 of the stopper 710 may be brought into contact with a first cam 745 and a second cam 746 of a second hinge device 730. In an embodiment, the first cam 745 may be provided on the first rotator 741 or the first arm. The second cam 746 may be provided on the second rotator 742 or the second arm. In an embodiment, when the second housing 120 and the third housing 130 are switched from the folded state to the unfolded state, the stopper 710 may be brought into contact with the first cam 745 and the second cam 746 of the second hinge device 730 and move in the −z-axis direction with reference to FIG. 17C. Accordingly, the protrusion 711 of the stopper 710 may protrude with respect to the opening 721 of the second hinge housing 720, and be located in the space 200 formed when the second housing 120 and the third housing 130 are unfolded. In an embodiment, the protrusion 711 of the stopper 710 may protrude with respect to the opening 721 in the second hinge housing 720 to form a substantially flat surface together with the second housing 120 and the third housing 130 in the state in which the second housing 120 and the third housing 130 are unfolded in parallel to each other. In an embodiment, when the second housing 120 and the third housing 130 are to be further unfolded (e.g., when the second housing 120 and the third housing 130 are to be unfolded in excess of 180 degrees) due to external force applied thereto in the state in which the second housing 120 and the third housing 130 are unfolded in substantially parallel to each other, the second housing and the third housing may not be further unfolded since one end of the second housing 120 and one end of the third housing 130 are brought into contact with the stopper 710. Accordingly, the stopper 710 may prevent/block the second housing 120 and the third housing 130 from being excessively unfolded by the space 200 or step formed between the second housing 120 and the third housing 130 in the state in which the second housing 120 and the third housing 130 are unfolded in parallel to each other.

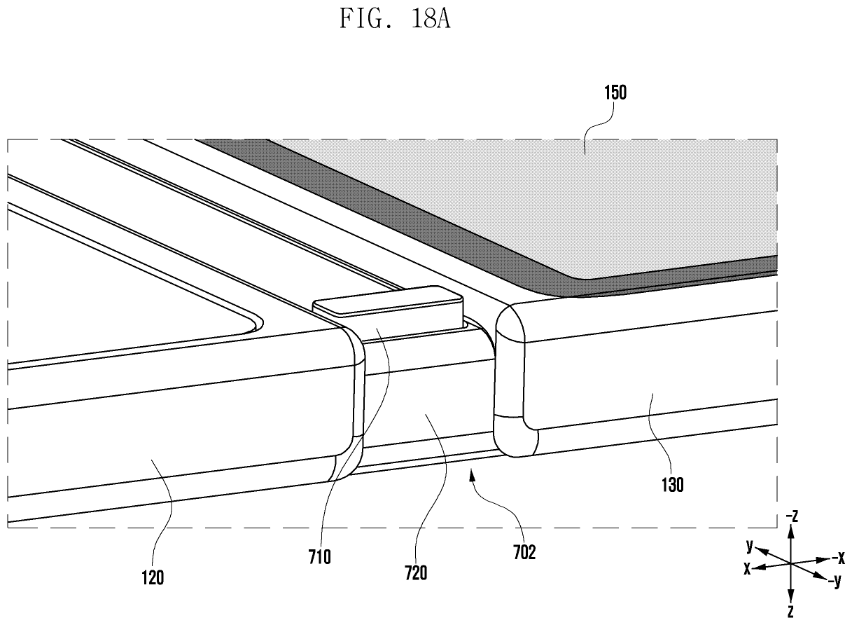

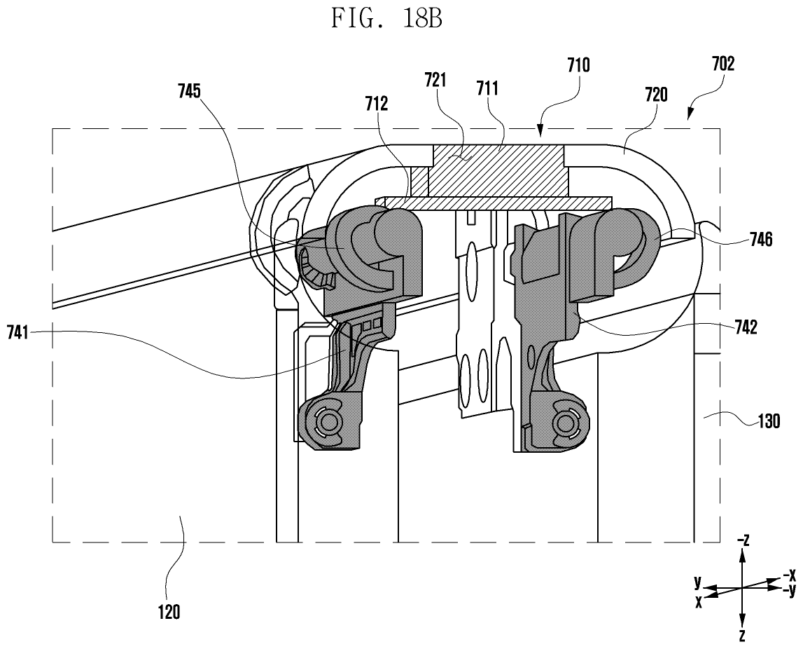

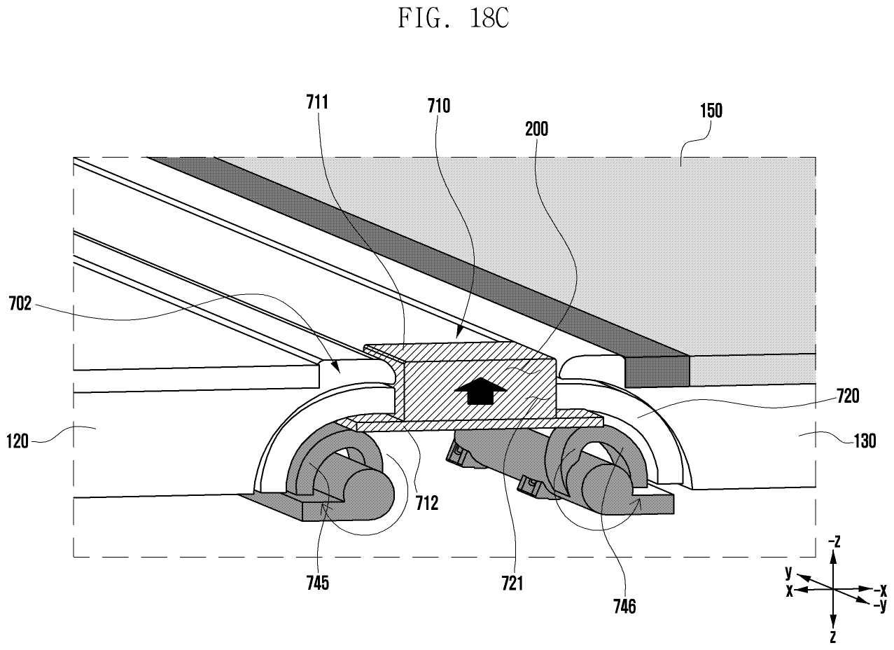

FIG. 18A is a perspective view illustrating a state in which a stopper configured to cooperate with a hinge device is located in one end portion of the second hinge, according to various embodiments. FIGS. 18B and 18C are perspective views illustrating an example process in which a stopper moves relative to a hinge housing in cooperation with a hinge device, according to various embodiments.

According to an embodiment, as illustrated in FIGS. 18A, 18B and 18C (which may be referred to as FIGS. 18A to 18C), the stopper 710 may be located only in one end portion (e.g., the configuration located in the +y-axis direction with reference to FIG. 18A) and the other end portion (e.g., the configuration located in the −y-axis direction with reference to FIG. 18A) of the second hinge 702 (e.g., the second hinge 102 in FIG. 5A and/or the second hinge 602 in FIG. 12A). In an embodiment, the second hinge housing 720 may include openings 721 which are provided in one end portion and the other end portion, respectively. In an embodiment, at least a portion the stopper 710 (e.g., the protrusion 711) may be located in each of the opening 721 provided in one end portion and the opening 721 provided in the other end portion of the second hinge housing 720. According to an embodiment, in the stopper 710 located in one end portion of the second hinge housing 720, one surface of the support 712 may be brought into contact with the first cam 745 and the second cam 746 of the second hinge device 730. In an embodiment, when the second housing 120 and the third housing 130 are switched from the folded state to the unfolded state, the stopper 710 may be brought into contact with the first cam 745 and the second cam 746 of the second hinge device 730 and move in the −z-axis direction with reference to FIG. 18C. According to an embodiment, in the stopper 710 located at the other end portion of the second hinge housing 720, one surface of the support 712 may be brought into contact with the third cam (not illustrated) and the fourth cam (not illustrated) of the second hinge device 730. In an embodiment, when the second housing 120 and the third housing 130 are switched from the folded state to the unfolded state, the stopper 710 may be brought into contact with the third cam and the fourth cam of the second hinge device 730 and move in the −z-axis direction with reference to FIG. 18C. Accordingly, the protrusion 711 of the stopper 710 may protrude with respect to the opening 721 of the second hinge housing 720, and be located in the space 200 formed when the second housing 120 and the third housing 130 are unfolded. In an embodiment, the protrusion 711 of the stopper 710 may protrude with respect to the opening 721 in the second housing 720 to form a substantially flat surface together with the second housing 120 and the third housing 130 in the state in which the second housing 120 and the third housing 130 are unfolded in parallel to each other. In an embodiment, when the second housing 120 and the third housing 130 are to be further unfolded (e.g., when the second housing 120 and the third housing 130 are to be unfolded in excess of 180 degrees) due to external force applied thereto in the state in which the second housing 120 and the third housing 130 are unfolded in substantially parallel to each other, the second housing and the third housing may not be further unfolded since one end of the second housing 120 and one end of the third housing 130 are brought into contact with the stopper 710. Accordingly, the stopper 710 may prevent/block the second housing 120 and the third housing 130 from being excessively unfolded by the space 200 or step formed between the second housing 120 and the third housing 130 in the state in which the second housing 120 and the third housing 130 are unfolded in parallel to each other.

In the foregoing description, the stoppers 710, which are located in one end portion and the other end portion of the second hinge housing 720, respectively, have been described on the assumption that the stoppers are in contact with the cams of the second hinge device 730, but the stoppers 710 may not be limited thereto. In an embodiment, the stoppers 710, which are located in one end portion and the other end portion of the second hinge housing 720, respectively, may cooperate with the second hinge device 730 through the cooperation method between the stopper 710 and the second hinge 730 described with reference to FIGS. 14A to 16B.

In addition, the accessory fastening structures provided on the second hinge 702 and/or the stoppers 610 and 710 of the second hinges 102, 602, and 702 described with reference to FIGS. 4A to 18C have been described on the assumption that they are applied to the multi-foldable electronic device 100 including the first housing 110, the second housing 120, and the third housing 130, but may not be limited thereto. In an embodiment, the accessory fastening structures provided on the second hinges 102, 602, and 702 illustrated in FIGS. 4A to 18C and/or the stoppers 610 and 710 of the second hinges 102, 602, and 702 may be equally applied to a foldable electronic device 100 including two housings.

An electronic device according to an example embodiment of the disclosure may include: a first housing, a second housing disposed on one side of the first housing and rotatably connected to the first housing, a third housing disposed on one side of the second housing and rotatably connected to the second housing, a first hinge provided between the first housing and the second housing and having a first width, and a second hinge provided between the second housing and the third housing and having a second width greater than the first width. The second hinge may include a fastening portion configured to receive a fastener of an accessory to fasten the accessory to the second hinge.

The second hinge may include a first coupling hole provided in one end portion thereof and configured such that a first fastener of the accessory is insertable thereinto, and a second coupling hole provided in the other end portion thereof and configured such that a second fastener is insertable thereinto.

The second hinge may include a first locking portion located within the first coupling hole wherein a first locking hole provided in the first fastener of the accessory is configured to be fastened to the first locking portion, and a second locking portion located within the second coupling hole wherein a second locking hole provided in the second fastener of the accessory is configured to be fastened to the second locking portion.

The second hinge may include a first release hole provided in a first direction perpendicular to an insertion direction of the first fastener of the accessory, the first release hole facing the first locking portion, and a second release hole provided in the first direction perpendicular to an insertion direction of the second fastener of the accessory, the second release hole facing the second locking portion. The accessory may be configured to allow the first fastener to be separated from the first locking portion based on the first locking portion being pressed in the first direction through the first release hole, and to allow the second fastener to be separated from the second locking portion based on the second locking portion being pressed in the first direction through the second release hole.

The first fastener may include a first cut portion configured to be inserted into the first coupling hole, and a second cut portion located outside one end portion of the second hinge to surround the one end portion of the second hinge, and the second fastener may include a third cut portion configured to be inserted into the second coupling hole, and a fourth cut portion located outside the other end portion of the second hinge to surround the other end portion of the second hinge.

The second hinge may include a first groove provided in an outer surface of one end portion thereof and configured such that a portion of a first hook on the accessory is insertable thereinto, and a second groove provided in an outer surface of the other end portion thereof and configured such that a portion of a second hook on the accessory is insertable thereinto.

According to an example embodiment disclosed herein, an electronic device may include: a plurality of housings rotatably connected to each other with a hinge interposed therebetween, and a stopper located in a space provided between the plurality of housings on the hinge based on the electronic device being unfolded.

The plurality of housings may include a first housing, a second housing disposed on one side of the first housing and rotatably connected to the first housing, and a third housing disposed on one side of the second housing and rotatably connected to the second housing. The hinge may include a first hinge provided between the first housing and the second housing and having a first width, and a second hinge provided between the second housing and the third housing and having a second width greater than the first width, the second hinge comprising the stopper.

The hinge may include a hinge device, comprising a hinge, coupled to the plurality of housings, and a hinge housing configured to cover at least a portion of the hinge device and including the stopper, at least a portion of the hinge housing defining an exterior of the electronic device.

The second hinge may include a fastening portion configured to receive a fastener of an accessory to be fastened thereto.

The stopper may include a first coupling hole provided at one end portion thereof and configured such that a first fastener of the accessory is insertable thereinto, and a second coupling hole provided at an other end portion thereof and configured such that a second fastener is insertable thereinto.

The hinge may include a hinge device comprising a hinge coupled to the plurality of housings, and a hinge housing configured to cover at least a portion of the hinge device and provided with an opening, at least a portion of the hinge housing defining an exterior of the electronic device, and based on the plurality of housings rotating, the stopper is configured to cooperate with the hinge device to protrude with respect to the opening in the hinge housing.

The stopper may include a protrusion protruding from the opening based on the electronic device being in the unfolded state, and a support connected to the protrusion and in contact with the hinge device.

The hinge device may include a first rotator coupled to one of the plurality of housings and including a first rotation part configured to rotate about a first rotation axis, and a second rotator coupled to the remaining one of the plurality of housings and including a second rotation part configured to rotate about a second rotation axis. The stopper may be configured such that one surface of the support is in contact with the first rotation part and the second rotation part.

The support may include a first bent portion having a radius of curvature equal to that of the first rotation part, and a second bent portion having a radius of curvature equal to that of the second rotation part.

The electronic device may further include an elastic member including a material configured to have an elastic restoring force disposed between the support and the hinge housing.

The hinge device may include a first rotator coupled to one of the plurality of housings, configured to rotate about a first rotation axis, and including a first gear, and a second rotator coupled to a remaining one of the plurality of housings, configured to rotate about a second rotation axis, and including a second gear. The stopper may include a rack gear configured to cooperate with the first gear and the second gear.

The hinge device may include at least one first pinion gear configured to cooperate with the first gear and the rack gear, and at least one second pinion gear configured to cooperate with the second gear and the rack gear.

The hinge device may include a first rotator coupled to one of the plurality of housings and configured to rotate about a first rotation axis, a second rotator coupled to a remaining one of the plurality of housings and configured to rotate about a second rotation axis, a first magnet disposed on one surface of the support of the stopper, a second magnet disposed on the first rotator and configured to exert repulsive force with the first magnet based on the electronic device being in the unfolded state, and a third magnet disposed on the second rotator and configured to exert repulsive force with the first magnet based on the electronic device being in the unfolded state.

The hinge device may include a first rotator coupled to one of the plurality of housings and including a first cam configured to rotate about a first rotation axis; and a second rotator coupled to the remaining one of the plurality of housings and including a second cam configured to rotate about a second rotation axis. The stopper may be configured such that one surface of the support is in contact with the first cam and the second cam.

The electronic device according to various embodiments set forth herein may be one of various types of electronic devices. The electronic device may include, for example, a portable communication device (e.g., a smart phone), a computer device, a portable multimedia device, a portable medical device, a camera, a wearable device, a home appliance, or the like.

The electronic device according to embodiments of the disclosure is not limited to those described above. It should be appreciated that various embodiments of the disclosure and the terms used therein are not intended to limit the technological features set forth herein to particular embodiments and the disclosure includes various changes, equivalents, or alternatives for a corresponding embodiment. With regard to the description of the drawings, similar reference numerals may be used to designate similar or relevant elements. A singular form of a noun corresponding to an item may include one or more of the items, unless the relevant context clearly indicates otherwise. As used herein, each of such phrases as “A or B,” “at least one of A and B,” “at least one of A or B,” “A, B, or C,” “at least one of A, B, and C,” and “at least one of A, B, or C,” may include any one or all possible combinations of the items enumerated together in a corresponding one of the phrases. Such terms as “a first,” “a second,” “the first,” and “the second” may be used to simply distinguish a corresponding element from another, and does not limit the elements in other aspect (e.g., importance or order). If an element (e.g., a first element) is referred to, with or without the term “operatively” or “communicatively”, as “coupled with/to” or “connected with/to” another element (e.g., a second element), the element may be coupled/connected with/to the other element directly (e.g., wiredly), wirelessly, or via a third element.

As used in various embodiments of the disclosure, the term “module” may include a unit implemented in hardware, software, or firmware, or any combination thereof, and may be interchangeably used with other terms, for example, “logic,” “logic block,” “component,” or “circuit”. The “module” may be a single integrated component, or a minimum unit or part thereof, adapted to perform one or more functions. For example, according to an embodiment, the “module” may be implemented in the form of an application-specific integrated circuit (ASIC).

According to various embodiments, each element (e.g., a module or a program) of the above-described elements may include a single entity or multiple entities, and some of the multiple entities may be separately disposed in any other element. According to various embodiments, one or more of the above-described elements or operations may be omitted, or one or more other elements or operations may be added. Alternatively or additionally, a plurality of elements (e.g., modules or programs) may be integrated into a single element. In such a case, according to various embodiments, the integrated element may still perform one or more functions of each of the plurality of elements in the same or similar manner as they are performed by a corresponding one of the plurality of elements before the integration. According to various embodiments, operations performed by the module, the program, or another element may be carried out sequentially, in parallel, repeatedly, or heuristically, or one or more of the operations may be executed in a different order or omitted, or one or more other operations may be added.

While the disclosure has been illustrated and described with reference to various example embodiments, it will be understood that the various example embodiments are intended to be illustrative, not limiting. It will be further understood by those skilled in the art that various changes in form and detail may be made without departing from the true spirit and full scope of the disclosure, including the appended claims and their equivalents. It will also be understood that any of the embodiment(s) described herein may be used in conjunction with any other embodiment(s) described herein.

What is claimed is:

1. An electronic device comprising:
a first housing;
a second housing disposed on one side of the first housing and rotatably connected to the first housing;
a third housing disposed on one side of the second housing and rotatably connected to the second housing;
a first hinge provided between the first housing and the second housing and having a first width; and
a second hinge provided between the second housing and the third housing and having a second width greater than the first width,
wherein the second hinge comprises a fastener receiving portion configured to receive a fastener of an accessary to be fastened to the electronic device.

2. The electronic device of claim 1, wherein the second hinge comprises a first coupling hole provided at one end portion thereof and configured such that a first fastener of the accessory is insertable thereinto, and a second coupling hole provided at another end portion thereof and configured such that a second of the accessory is insertable thereinto.

3. The electronic device of claim 2, wherein the second hinge comprises a first locking portion located within the first coupling hole wherein a first locking hole provided in the first fastener of the accessory is configured to be fastened to the first locking portion, and a second locking portion located within the second coupling hole wherein a second locking hole provided in the second fastener of the accessory is configured to be fastened to the second locking portion.

4. The electronic device of claim 3, wherein the second hinge comprises a first release hole provided in a first direction perpendicular to an insertion direction of the first fastener of the accessory, the first release hole facing the first locking portion, and a second release hole provided in the first direction perpendicular to an insertion direction of the second fastener of the accessory, the second release hole facing the second locking portion, and
wherein the accessory is configured to allow the first fastener to be separated from the first locking portion based on the first locking portion being pressed in the first direction through the first release hole, and to allow the second fastener to be separated from the second locking portion based on the second locking portion being pressed in the first direction through the second release hole.

5. The electronic device of claim 2, wherein the first fastener comprises a first cut portion configured to be inserted into the first coupling hole, and a second cut portion located outside one end portion of the second hinge to surround the one end portion of the second hinge, and
wherein the second fastener comprises a third cut portion configured to be inserted into the second coupling hole, and a fourth cut portion located outside another end portion of the second hinge to surround the another end portion of the second hinge.

6. The electronic device of claim 1, wherein the second hinge comprises a first groove provided in an outer surface of one end portion thereof and configured such that a portion of a first hook on the accessory is insertable thereinto, and a second groove provided in an outer surface of another end portion thereof and configured such that a portion of a second hook on the accessory is insertable thereinto.

7. An electronic device comprising:
a plurality of housings rotatably connected to each other with a hinge interposed therebetween; and
a stopper located in a space provided between the plurality of housings on the hinge based on the electronic device being unfolded.

8. The electronic device of claim 7, wherein the plurality of housings comprise:
a first housing;
a second housing disposed on one side of the first housing and rotatably connected to the first housing; and
a third housing disposed on one side of the second housing and rotatably connected to the second housing;
wherein the hinge comprises:
a first hinge provided between the first housing and the second housing and having a first width; and
a second hinge provided between the second housing and the third housing and having a second width greater than the first width, the second hinge comprising the stopper.

9. The electronic device of claim 7, wherein the hinge comprises:
a hinge device comprising a hinge coupled to the plurality of housings; and
a hinge housing configured to cover at least a portion of the hinge device and provided with the stopper, at least a portion of the hinge housing defining an exterior of the electronic device.

10. The electronic device of claim 8, wherein the second hinge comprises a fastening structure comprising a fastener receiving portion configured to receive a fastener of an accessory configured to be fastened to the electronic device.

11. The electronic device of claim 10, wherein the stopper comprises a first coupling hole provided in one end portion thereof and configured such that a first fastener of the accessory is insertable thereinto, and a second coupling hole provided at another end portion thereof and configured such that a second fastener of the accessory is insertable thereinto.

12. The electronic device of claim 7, wherein the hinge comprises:
a hinge device including a hinge coupled to the plurality of housings; and
a hinge housing configured to cover at least a portion of the hinge device and provided with an opening, at least a portion of the hinge housing defining an exterior of the electronic device, and
wherein, based on the plurality of housings rotating, the stopper is configured to cooperate with the hinge device to protrude with respect to the opening in the hinge housing.

13. The electronic device of claim 12, wherein the stopper includes a protrusion protruding from the opening in a state in which the electronic device is unfolded, and a support connected to the protrusion and configured to be in contact with the hinge device.

14. The electronic device of claim 13, wherein the hinge device comprises:
a first rotator coupled to one of the plurality of housings and comprising a first rotation part configured to rotate about a first rotation axis; and
a second rotator coupled to a remaining one of the plurality of housings and comprising a second rotation part configured to rotate about a second rotation axis, and
wherein the stopper is configured such that one surface of the support is in contact with the first rotation part and the second rotation part.

15. The electronic device of claim 14, wherein the support comprises:
a first bent portion having a radius of curvature equal to a radius of curvature of the first rotation part; and
a second bent portion having a radius of curvature equal to a radius of curvature of the second rotation part.

16. The electronic device of claim 14, further comprising
an elastic member comprising a material configured to have an elastic restoring force disposed between the support and the hinge housing.

17. The electronic device of claim 12, wherein the hinge device comprises:
a first rotator coupled to one of the plurality of housings, configured to rotate about a first rotation axis, and comprising a first gear;
a second rotator coupled to a remaining one of the plurality of housings, configured to rotate about a second rotation axis, and comprising a second gear, and
wherein the stopper comprises a rack gear configured to cooperate with the first gear and the second gear.

18. The electronic device of claim 17, wherein the hinge device comprises:
at least one first pinion gear configured to cooperate with the first gear and the rack gear; and
at least one second pinion gear configured to cooperate with the second gear and the rack gear.

19. The electronic device of claim 13, wherein the hinge device comprises:
a first rotator coupled to one of the plurality of housings and configured to rotate about a first rotation axis;
a second rotator coupled to a remaining one of the plurality of housings and configured to rotate about a second rotation axis;
a first magnet disposed on one surface of the support of the stopper;
a second magnet disposed on the first rotator and configured to exert repulsive force with the first magnet in a state in which the electronic device is unfolded; and
a third magnet disposed on the second rotator and configured to exert repulsive force with the first magnet in a state in which the electronic device is unfolded.

20. The electronic device of claim 13, wherein the hinge device comprises:
a first rotator coupled to one of the plurality of housings and comprising a first cam configured to rotate about a first rotation axis; and
a second rotator coupled to a remaining one of the plurality of housings and comprising a second cam configured to rotate about a second rotation axis, and
wherein the stopper is configured such that one surface of the support is in contact with the first cam and the second cam.
